(19) United States
(12) Patent Application Publication
(10) Pub. No.: US 2026/0279278 A1
(43) Pub. Date: Sep. 17, 2026

(54) DISPLAY PANEL AND DISPLAY DEVICE

(71) Applicants: Chengdu BOE Optoelectronics Technology Co., Ltd., Chengdu, Sichuan (CN); BOE Technology Group Co., Ltd., Beijing (CN); Beijing BOE Technology Development Co., Ltd., Beijing (CN)

(72) Inventor: Changlong YUAN, Beijing (CN)

(21) Appl. No.: 19/168,248

(22) PCT Filed: Jul. 5, 2024
(86) PCT No.: PCT/CN2024/104010

§ 371 Date: Sep. 23, 2025

(30) Foreign Application Priority Data
Aug. 24, 2023 (CN) 202311077017.2

(51) Int. Cl. G09G 3/3233; G11C 19/28; H10K 59/131

(52) U.S. Cl. CPC G09G 3/3233; H10K 59/131; G09G 2300/0819; G09G 2300/0852; G09G 2300/0861; G09G 2310/0286; G09G 2310/08; G09G 2330/02; G11C 19/28

(57) ABSTRACT

A display panel includes a display area and a non-display area. The display area includes sub-pixels and control signal lines. Each sub-pixel includes a pixel circuit.. The pixel circuit includes a light-emitting device, a driving transistor, a data writing circuit and a pixel control circuit. The pixel control circuit is configured to control the driving transistor to generate a driving current for driving the light-emitting device to emit light. Pixel circuits in at least one row of sub-pixels are coupled to one control signal line. Control signal lines corresponding to at least two adjacent rows of sub-pixels are coupled to each other. The non-display area includes a drive control circuit including shift register units. Control signal lines coupled to each other are coupled to one shift register unit. The shift register unit is configured to transmit a signal to pixel circuits through the control signal lines.

### CROSS-REFERENCE TO RELATED APPLICATIONS

This application is a national phase entry under 35 U.S.C. § 371 of International Application No. PCT/CN2024/104010, filed on Jul. 5, 2024, which claims priority to Chinese Patent Application No. 202311077017.2, filed with the China National Intellectual Property Administration on Aug. 24, 2023, and entitled “Display Panel and Display Device”, the entire contents of which are incorporated herein by reference.

### TECHNICAL FIELD

The present disclosure relates to the field of display technology, and in particular to a display panel and a display device.

### BACKGROUND

Light-emitting devices such as Organic Light Emitting Diode (OLED), Quantum Dot Light Emitting Diodes (QLED), Micro Light Emitting Diode (Micro LED), and Mini Light Emitting Diode (Mini LED) have the advantages of self-luminescence and low energy consumption, and are one of the hot topics in the current research field of display device applications. In general, a pixel circuit is used in a display device to drive a light-emitting device to emit light.

### SUMMARY

Embodiments of the present disclosure provide a display panel, including: a display area and a non-display area.

The display area includes: a plurality of sub-pixels and a plurality of control signal lines. Each of the plurality of sub-pixels includes a pixel circuit. The pixel circuit includes: a light-emitting device, a driving transistor, a data writing circuit, and a pixel control circuit. The driving transistor is coupled to the data writing circuit and the pixel control circuit respectively. The data writing circuit is configured to provide a data voltage at a data signal terminal to a gate of the driving transistor in response to a scan signal at a scan signal terminal. The pixel control circuit is configured to control the driving transistor to generate a driving current for driving the light-emitting device to emit light.

Pixel circuits in at least one row of sub-pixels among the plurality of sub-pixels are coupled to one control signal line among the plurality of control signal lines. Control signal lines corresponding to at least two adjacent rows of sub-pixels are coupled to each other.

The non-display area includes a drive control circuit. The drive control circuit includes a plurality of shift register units. The control signal lines coupled to each other are coupled to one shift register unit among the plurality of shift register units. The shift register unit is configured to transmit a signal to pixel circuits through the control signal lines.

In some embodiments, the pixel circuit includes a first light emitting control circuit. The first light emitting control circuit is coupled to a first electrode of the driving transistor, a first light emitting control signal terminal and a first power terminal. The first light emitting control circuit is configured to provide a signal at the first power terminal to the first electrode of the driving transistor in response to a first light emitting control signal at the first light emitting control signal terminal.

The display area further includes a plurality of first light emitting control signal lines. First light emitting control signal terminals of pixel circuits in at least one row of sub-pixels among the plurality of sub-pixels are coupled to one first light emitting control signal line among the plurality of first light emitting control signal lines.

In some embodiments, the pixel control circuit includes the first light emitting control circuit. The drive control circuit includes a first light-emitting drive control circuit. The first light-emitting drive control circuit includes a plurality of first light-emitting shift register units. The shift register units include the first light-emitting shift register units. The control signal lines include the first light emitting control signal lines.

First light emitting control signal lines corresponding to at least two adjacent rows of sub-pixels are coupled to each other and then coupled to one first light-emitting shift register units among the plurality of first light-emitting shift register units.

In some embodiments, the display area includes a plurality of display sub-areas. The plurality of display sub-areas are arranged along a column direction of the sub-pixels. The plurality of first light-emitting shift register units include a plurality of first light-emitting register groups. The plurality of first light-emitting register groups correspond one-to-one to the plurality of display sub-areas. The plurality of first light-emitting register groups are coupled to the first light emitting control signal lines in corresponding display sub-areas.

The plurality of first light-emitting register groups correspond one-to-one to a plurality of first light-emitting trigger signal terminals. An input signal terminal of a first-level first light-emitting shift register unit in the first light-emitting register group is coupled to a corresponding first light-emitting trigger signal terminal. Alternatively, the plurality of first light-emitting register groups correspond to one first light-emitting trigger signal terminal. An input signal terminal of a first-level first light-emitting shift register unit in a first-level first light-emitting register group among the plurality of first light-emitting register groups is coupled to the one first light-emitting trigger signal terminal. A driving output terminal of a last-level first light-emitting shift register unit in a preceding-level first light-emitting register group of two adjacent first light-emitting register groups is coupled to the input signal terminal of the first-level first light-emitting shift register unit in a following-level first light-emitting register group.

In some embodiments, the non-display area further includes a second light-emitting drive control circuit. The second light-emitting drive control circuit includes a plurality of second light-emitting shift register units.

The first light emitting control signal line corresponding to pixel circuits in each row of sub-pixels in the plurality of sub-pixels is coupled to one second light-emitting shift register unit among the plurality of second light-emitting shift register units.

In some embodiments, the display area includes a plurality of display sub-areas. The plurality of display sub-areas are arranged along a column direction of the sub-pixels. The plurality of second light-emitting shift register units include a plurality of second light-emitting register groups. The plurality of second light-emitting register groups correspond to the plurality of display sub-areas one by one. The plurality of second light-emitting register groups are coupled to the first light emitting control signal lines in the corresponding display sub-areas.

The plurality of second light-emitting register groups correspond one-to-one to a plurality of second light-emitting trigger signal terminals. An input signal terminal of a first-level second light-emitting shift register unit in the second light-emitting register group is coupled to a corresponding second light-emitting trigger signal terminal. Alternatively, the plurality of second light-emitting register groups correspond to one second light-emitting trigger signal terminal. An input signal terminal of a first-level second light-emitting shift register unit in a first-level second light-emitting register group among the plurality of second light-emitting register groups is coupled to the one second light-emitting trigger signal terminal. The driving output terminal of a last-level second light-emitting shift register unit in a preceding-level second light-emitting register group of two adjacent second light-emitting register groups is coupled to the input signal terminal of the first-level second light-emitting shift register unit in a following-level second light-emitting register group.

In some embodiments, the pixel circuit includes a second light emitting control circuit. The second light emitting control circuit is coupled to the second electrode of the driving transistor, the light-emitting device and a second light emitting control signal terminal. The second light emitting control circuit is configured to enable conduction between the second electrode of the driving transistor and the light-emitting device in response to a second light emitting control signal at the second light emitting control signal terminal.

The display area further includes a plurality of second light emitting control signal lines. Second light emitting control signal terminals of pixel circuits in at least one row of sub-pixels among the plurality of sub-pixels are coupled to one second light emitting control signal line among the plurality of second light emitting control signal lines.

In some embodiments, the pixel control circuit includes the second light emitting control circuit. The drive control circuit includes a third light-emitting drive control circuit. The third light-emitting drive control circuit includes a plurality of third light-emitting shift register units. The shift register units include the third light-emitting shift register units.

The control signal lines include the second light emitting control signal lines. The second light emitting control signal lines corresponding to at least two adjacent rows of sub-pixels are coupled to each other and then coupled to one third light-emitting shift register unit among the plurality of third light-emitting shift register units.

In some embodiments, the display area includes a plurality of display sub-areas. The plurality of display sub-areas are arranged along a column direction of the sub-pixels. The plurality of third light-emitting shift register units include a plurality of third light-emitting register groups. The plurality of third light-emitting register groups correspond to the plurality of display sub-areas one by one. The plurality of third light-emitting register groups are coupled to the second light emitting control signal lines in the corresponding display sub-areas.

The plurality of third light-emitting register groups correspond one-to-one to a plurality of third light-emitting trigger signal terminals. The input signal terminal of the first-level third light-emitting shift register unit in the third light-emitting register group is coupled to the corresponding third light-emitting trigger signal terminal. Alternatively, the plurality of third light-emitting register groups correspond to one third light-emitting trigger signal terminal. The input signal terminal of the first-level third light-emitting shift register unit in the first-level third light-emitting register group among the plurality of third light-emitting register groups is coupled to the one third light-emitting trigger signal terminal. The driving output terminal of the last-level third light-emitting shift register unit in the preceding-level third light-emitting register group of two adjacent third light-emitting register groups is coupled to the input signal terminal of the first-level third light-emitting shift register unit in the following-level third light-emitting register group.

In some embodiments, the non-display area further includes a fourth light-emitting drive control circuit. The fourth light-emitting drive control circuit includes a plurality of fourth light-emitting shift register units.

The second light emitting control signal line corresponding to the pixel circuits in each row of sub-pixels in the plurality of sub-pixels is coupled to one fourth light-emitting shift register unit among the plurality of fourth light-emitting shift register units.

In some embodiments, the display area includes a plurality of display sub-areas. The plurality of display sub-areas are arranged along a column direction of the sub-pixels. The plurality of fourth light-emitting shift register units include a plurality of fourth light-emitting register groups. The plurality of fourth light-emitting register groups correspond to the plurality of display sub-areas one by one. The plurality of fourth light-emitting register groups are coupled to the second light emitting control signal lines in the corresponding display sub-areas.

The plurality of fourth light-emitting register groups correspond one-to-one to a plurality of fourth light-emitting trigger signal terminals. The input signal terminal of the first-level fourth light-emitting shift register unit in the fourth light-emitting register group is coupled to a corresponding fourth light-emitting trigger signal terminal. Alternatively, the plurality of fourth light-emitting register groups correspond to one fourth light-emitting trigger signal terminal. The input signal terminal of the first-level fourth light-emitting shift register unit in the first fourth light-emitting register group among the plurality of fourth light-emitting register groups is coupled to the one fourth light-emitting trigger signal terminal. The driving output terminal of the last-level fourth light-emitting shift register unit in the previous fourth light-emitting register group of two adjacent fourth light-emitting register groups is coupled to the input signal terminal of the first-level fourth light-emitting shift register unit in the following-level fourth light-emitting register group.

In some embodiments, the pixel circuit includes a first reset control circuit. The first reset control circuit is coupled to the gate of the driving transistor, a first reset control signal terminal, and a reference signal terminal. The first reset control circuit is configured to provide a signal at the reference signal terminal to the gate of the driving transistor in response to a first reset control signal at the first reset control signal terminal.

The display area further includes a plurality of first reset control signal lines. First reset control signal terminals of pixel circuits in at least one row of sub-pixels among the plurality of sub-pixels are coupled to one first reset control signal line among the plurality of first reset control signal lines.

In some embodiments, the pixel control circuit includes the first reset control circuit. The drive control circuit includes a first reset drive control circuit. The first reset drive control circuit includes a plurality of first reset shift register units. The shift register units include the first reset shift register units.

The control signal lines include the first reset control signal lines. The first reset control signal lines corresponding to at least two adjacent rows of sub-pixels are coupled to each other and then coupled to one first reset shift register units among the plurality of first reset shift register units.

In some embodiments, the display area includes a plurality of display sub-areas. The plurality of display sub-areas are arranged along the column direction of the sub-pixels. The plurality of first reset shift register units include a plurality of first reset register groups. The plurality of first reset register groups correspond to the plurality of display sub-areas one by one. The plurality of first reset register groups are coupled to the first reset control signal lines in the corresponding display sub-areas.

The plurality of first reset register groups correspond one-to-one to the plurality of first reset trigger signal terminals. The input signal terminal of the first-level first reset shift register unit in the first reset register group is coupled to the corresponding first reset trigger signal terminal. Alternatively, the plurality of first reset register groups correspond to one first reset trigger signal terminal. The input signal terminal of the first-level first reset shift register unit in the first-level first reset register group among the plurality of first reset register groups is coupled to the one first reset trigger signal terminal. The driving output terminal of the last-level first reset shift register unit in the preceding-level first reset register group of two adjacent first reset register groups is coupled to the input signal terminal of the first-level first reset shift register unit in the following-level first reset register group.

In some embodiments, the non-display area further includes a second reset drive control circuit. The second reset drive control circuit includes a plurality of second reset shift register units.

The first reset control signal line corresponding to the pixel circuits in each row of sub-pixels in the plurality of sub-pixels is coupled to one second reset shift register unit among the plurality of second reset shift register units.

In some embodiments, the display area includes a plurality of display sub-areas. The plurality of display sub-areas are arranged along the column direction of the sub-pixels. The plurality of second reset shift register units include a plurality of second reset register groups. The plurality of second reset register groups correspond to the plurality of display sub-areas one by one. The plurality of second reset register groups are coupled to the first reset control signal lines in the corresponding display sub-areas.

The plurality of second reset register groups correspond one-to-one to the plurality of second reset trigger signal terminals. The input signal terminal of the first-level second reset shift register unit in the second reset register group is coupled to the corresponding second reset trigger signal terminal. Alternatively, the plurality of second reset register groups correspond to one second reset trigger signal terminal. The input signal terminal of the first-level second reset shift register unit in the first second reset register group among the plurality of second reset register groups is coupled to the one second reset trigger signal terminal. The driving output terminal of the last-level second reset shift register unit in the preceding-level second reset register group of two adjacent second reset register groups is coupled to the input signal terminal of the first-level second reset shift register unit in the following-level second reset register group.

In some embodiments, the pixel circuit includes a second reset control circuit. The second reset control circuit is coupled to the second electrode of the driving transistor, the second reset control signal terminal, and the first initialization signal terminal. The second reset control circuit is configured to provide a signal at the first initialization signal terminal to the second electrode of the driving transistor in response to a second reset control signal at the second reset control signal terminal.

The display area further includes a plurality of second reset control signal lines. The second reset control signal terminals of the pixel circuits in at least one row of sub-pixels among the plurality of sub-pixels are coupled to one second reset control signal line among the plurality of second reset control signal lines.

In some embodiments, the pixel control circuit includes the second reset control circuit. The drive control circuit includes a third reset drive control circuit. The third reset drive control circuit includes a plurality of third reset shift register units. The shift register units include the third reset shift register units.

The control signal lines include the second reset control signal lines. The second reset control signal lines corresponding to at least two adjacent rows of sub-pixels are coupled to each other and then coupled to one third reset shift register units among the plurality of third reset shift register units.

In some embodiments, the display area includes a plurality of display sub-areas. The plurality of display sub-areas are arranged along the column direction of the sub-pixels. The plurality of third reset shift register units include a plurality of third reset register groups. The plurality of third reset register groups correspond to the plurality of display sub-areas one by one. The plurality of third reset register groups are coupled to the second reset control signal lines in the corresponding display sub-areas.

The plurality of third reset register groups correspond one-to-one to a plurality of third reset trigger signal terminals. The input signal terminal of the first-level third reset shift register unit in the third reset register group is coupled to the corresponding third reset trigger signal terminal. Alternatively, the plurality of third reset register groups correspond to one third reset trigger signal terminal. The input signal terminal of the first-level third reset shift register unit in the first-level third reset register group among the plurality of third reset register groups is coupled to the one third reset trigger signal terminal. The driving output terminal of the last-level third reset shift register unit in the preceding-level third reset register group of two adjacent third reset register groups is coupled to the input signal terminal of the first-level third reset shift register unit in the following-level third reset register group.

In some embodiments, the non-display area further includes a fourth reset drive control circuit. The fourth reset drive control circuit includes a plurality of fourth reset shift register units.

The second reset control signal line corresponding to the pixel circuits in each row of sub-pixels in the plurality of sub-pixels is coupled to one of the plurality of fourth reset shift register units.

In some embodiments, the display area includes a plurality of display sub-areas. The plurality of display sub-areas are arranged along the column direction of the sub-pixels. The plurality of fourth reset shift register units include a plurality of fourth reset register groups. The plurality of fourth reset register groups correspond to the plurality of display sub-areas one by one. The plurality of fourth reset register groups are coupled to the second reset control signal lines in the corresponding display sub-areas.

The plurality of fourth reset register groups correspond one-to-one to the plurality of fourth reset trigger signal terminals. The input signal terminal of the first-level fourth reset shift register unit in the fourth reset register group is coupled to the corresponding fourth reset trigger signal terminal. Alternatively, the plurality of fourth reset register groups correspond to one fourth reset trigger signal terminal. The input signal terminal of the first-level fourth reset shift register unit in the first-level fourth reset register group among the plurality of fourth reset register groups is coupled to the one fourth reset trigger signal terminal. The driving output terminal of the last-level fourth reset shift register unit in the preceding-level fourth reset register group of two adjacent fourth reset register groups is coupled to the input signal terminal of the first-level fourth reset shift register unit in the following-level fourth reset register group.

In some embodiments, the pixel circuit includes a third reset control circuit. The third reset control circuit is coupled to the light-emitting device, a third reset control signal terminal and a second initialization signal terminal. The third reset control circuit is configured to provide a signal at the second initialization signal terminal to the light-emitting device in response to a third reset control signal at the third reset control signal terminal.

The display area further includes a plurality of third reset control signal lines. The third reset control signal terminals of the pixel circuits in at least one row of sub-pixels among the plurality of sub-pixels are coupled to one third reset control signal line among the plurality of third reset control signal lines.

In some implementations, the third reset control signal terminal and the second reset control signal terminal are connected to the same signal. The third reset control signal line and the second reset control signal line are the same signal line.

In some embodiments, the pixel circuit further includes at least one of a first capacitor and a second capacitor.

A first end of the first capacitor is coupled to the gate electrode of the driving transistor, and a second end of the first capacitor is coupled to the second electrode of the driving transistor.

The first end of the second capacitor is coupled to the second electrode of the driving transistor, and the second end of the second capacitor is coupled to the fixed voltage end.

In some embodiments, the light-emitting device is further coupled to a second power terminal.

The fixed voltage terminal is connected to the same signal as one of the first power terminal, the reference signal terminal, the first initialization signal terminal, the second initialization signal terminal and the second power terminal.

Embodiments of the present disclosure further provide a display device, including the above-mentioned display panel.

### BRIEF DESCRIPTION OF DRAWINGS

FIG. 1 is a schematic diagram of some structures in a pixel circuit in an embodiment of the present disclosure.

FIG. 2 is a schematic diagram of some structures in a pixel circuit in an embodiment of the present disclosure.

FIG. 3A is a schematic diagram of some structures in a pixel circuit in an embodiment of the present disclosure.

FIG. 3B is a timing diagram of some signals in an embodiment of the present disclosure.

FIG. 4A is a schematic diagram of some structures in a pixel circuit in an embodiment of the present disclosure.

FIG. 4B is a timing diagram of some signals in an embodiment of the present disclosure.

FIG. 5A is a schematic diagram of some structures in a display panel in an embodiment of the present disclosure.

FIG. 5B is a schematic diagram of some structures in a display panel in an embodiment of the present disclosure.

FIG. 6 is a timing diagram of some signals in an embodiment of the present disclosure.

FIG. 7 is a schematic diagram of some structures in a display panel in an embodiment of the present disclosure.

FIG. 8A is a timing diagram of some signals in an embodiment of the present disclosure.

FIG. 8B is a timing diagram of some signals in an embodiment of the present disclosure.

FIG. 9A is a timing diagram of some signals in an embodiment of the present disclosure.

FIG. 9B is a timing diagram of some signals in an embodiment of the present disclosure.

FIG. 10A is a timing diagram of some signals in an embodiment of the present disclosure.

FIG. 10B is a timing diagram of some signals in an embodiment of the present disclosure.

FIG. 11A is a schematic diagram of some structures in a display panel in an embodiment of the present disclosure.

FIG. 11B is a schematic diagram of some structures in a display panel in an embodiment of the present disclosure.

FIG. 12 is a timing diagram of some signals in an embodiment of the present disclosure.

FIG. 13A is a schematic diagram of some structures in a display panel in an embodiment of the present disclosure.

FIG. 13B is a schematic diagram of some structures in a display panel in an embodiment of the present disclosure.

FIG. 14 is a timing diagram of some signals in an embodiment of the present disclosure.

FIG. 15A is a schematic diagram of some structures in a display panel in an embodiment of the present disclosure.

FIG. 15B is a schematic diagram of some structures in a display panel in an embodiment of the present disclosure.

FIG. 16 is a timing diagram of some signals in an embodiment of the present disclosure.

FIG. 17A is a schematic diagram of some structures in a display panel in an embodiment of the present disclosure.

FIG. 17B is a schematic diagram of some structures in a display panel in an embodiment of the present disclosure.

FIG. 18A is a schematic diagram of some structures in a display panel in an embodiment of the present disclosure.

FIG. 18B is a schematic diagram of some structures in a display panel in an embodiment of the present disclosure.

FIG. 19A is a schematic diagram of some structures in a display panel in an embodiment of the present disclosure.

FIG. 19B is a schematic diagram of some structures in a display panel in an embodiment of the present disclosure.

### DETAILED DESCRIPTION

In order to make the purpose, technical solution and advantages of the embodiments of the present disclosure more clear, the technical solution of the embodiments of the present disclosure will be clearly and completely described below in conjunction with the drawings of the embodiments of the present disclosure. Obviously, the described embodiments are only part of the embodiments of the present disclosure, rather than all the embodiments. Furthermore, the embodiments in the present disclosure and the features in the embodiments may be combined with each other without conflict. Based on the described embodiments of the present disclosure, all other embodiments obtained by those of ordinary skill in the art without creative work are within the scope of protection of the present disclosure.

Unless otherwise defined, technical or scientific terms used in the present disclosure should have the common meanings understood by a person having ordinary skills in the field to which the present disclosure belongs. The terms “first”, “second” and the like used in the present disclosure do not indicate any order, quantity or importance, but are only used to distinguish different components. The words “include” or “comprise” and the like mean that the elements or objects preceding the word include the elements or objects listed after the word and their equivalents, but do not exclude other elements or objects. The terms “coupled” or “connected” and the like are not limited to physical or mechanical coupling, but may include electrical coupling, whether direct or indirect.

It should be noted that the size and shape of each figure in the accompanying drawings do not reflect the actual proportion, and the purpose is only to illustrate the contents of the present disclosure. And the same or similar reference numerals throughout represent the same or similar elements or elements having the same or similar functions.

In some embodiments of the present disclosure, the display device provided by the embodiments of the present disclosure may include a display panel. The display panel may include a display area and a non-display area (i.e., an area other than an area occupied by the display area). The display area may include a plurality of pixel units arranged in an array. Exemplarily, each pixel unit includes sub-pixels of the same color or sub-pixels of multiple different colors. For example, a pixel unit may include a red sub-pixel, a green sub-pixel, and a blue sub-pixel, so that color display can be achieved by mixing red, green, and blue. Alternatively, the pixel unit may also include a red sub-pixel, a green sub-pixel, a blue sub-pixel and a white sub-pixel, so that color display can be achieved by mixing red, green, blue and white. Of course, in practical applications, the luminous colors of the sub-pixels in the pixel unit can be designed and determined according to the actual application environment, and are not limited here. The following description is made by taking an example where a pixel unit includes a red sub-pixel, a green sub-pixel and a blue sub-pixel.

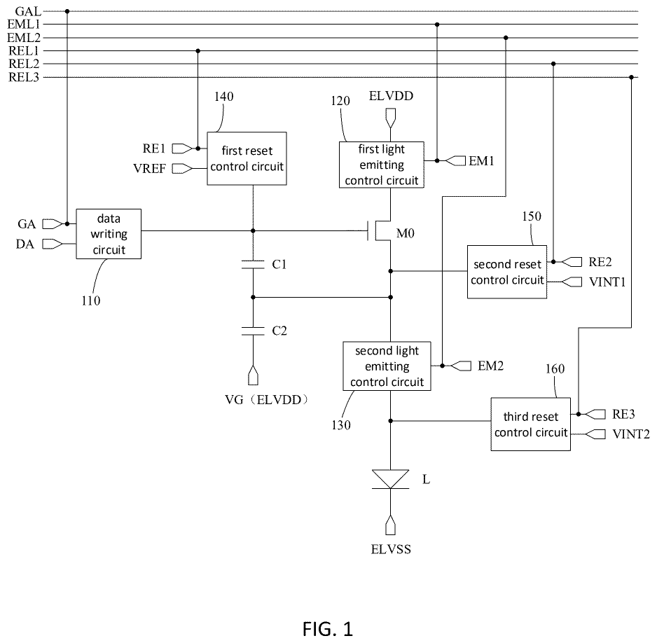

In some embodiments of the present disclosure, each sub-pixel may include a pixel circuit. The pixel circuit may include a driving transistor M0 and a light-emitting device L. The driving transistor M0 generates a driving current to drive the light-emitting device L to emit light, thereby enabling the display panel to display a picture. Exemplarily, as shown in FIG. 1, the pixel circuit includes a light-emitting device L. A cathode of the light-emitting device L may be coupled to a second power terminal ELVSS. Exemplarily, the light-emitting device L may be an electroluminescent diode. For example, the light-emitting device L may include at least one of a micro light emitting diode (Micro Light Emitting Diode, Micro LED), an organic light emitting diode (Organic Light Emitting Diode, OLED) and a quantum dot light emitting diode (Quantum Dot Light Emitting Diode, QLED). In practical applications, the structure of the light-emitting device can be designed and determined according to the actual application environment, and is not limited here.

Exemplarily, as shown in FIG. 1, the pixel circuit includes: a data writing circuit 110 configured to provide a data voltage at a data signal terminal DA to a gate of a driving transistor M0 in response to a scan signal at a scan signal terminal GA. In addition, the display area further includes a plurality of scan signal lines GAL. A row of sub-pixels in the plurality of sub-pixels corresponds to one scan signal line GAL in the plurality of scan signal lines GAL. The scan signal terminals GA of the data writing circuits 110 in a row of sub-pixels are coupled to the corresponding scan signal line GAL.

Exemplarily, as shown in FIG. 1, the pixel circuit includes a first light emitting control circuit 120. The first light emitting control circuit 120 is coupled to the first electrode of the driving transistor M0. The first light emitting control circuit 120 is configured to provide a signal at a first power terminal ELVDD to the first electrode of the driving transistor M0 in response to a first light emitting control signal at a first light emitting control signal terminal EM1. Furthermore, the display area further includes a plurality of first light emitting control signal lines EML1. The first light emitting control signal terminals EM1 of the pixel circuits in a row of sub-pixels among the plurality of sub-pixels are coupled to one first light emitting control signal line EML1 among the plurality of first light emitting control signal lines EML1.

Exemplarily, as shown in FIG. 1, the pixel circuit includes a second light emitting control circuit 130. The second light emitting control circuit 130 is coupled to the second electrode of the driving transistor M0 and the light-emitting device L. The second light emitting control circuit 130 is configured to enable conduction between the second electrode of the driving transistor M0 and the light-emitting device L in response to a second light emitting control signal at a second light emitting control signal terminal EM2. Furthermore, the display area further includes a plurality of second light emitting control signal lines EML2. The second light emitting control signal terminals EM2 of the pixel circuits in a row of sub-pixels among the plurality of sub-pixels are coupled to one second light emitting control signal line EML2 among the plurality of second light emitting control signal lines EML2.

Exemplarily, as shown in FIG. 1, the pixel circuit includes a first reset control circuit 140. The first reset control circuit 140 is coupled to the gate of the driving transistor M0. The first reset control circuit 140 is configured to provide a signal at a reference signal terminal VREF to the gate of the driving transistor M0 in response to a first reset control signal at a first reset control signal terminal RE1. Furthermore, the display area further includes a plurality of first reset control signal lines REL1. The first reset control signal terminals RE1 of the pixel circuits in a row of sub-pixels among the plurality of sub-pixels are coupled to one first reset control signal line REL1 among the plurality of first reset control signal lines REL1.

Exemplarily, as shown in FIG. 1, the pixel circuit includes a second reset control circuit 150. The second reset control circuit 150 is coupled to the second electrode of the driving transistor M0. The second reset control circuit 150 is configured to provide a signal at the first initialization signal terminal VINT1 to the second electrode of the driving transistor M0 in response to a second reset control signal at the second reset control signal terminal RE2. Furthermore, the display area further includes a plurality of second reset control signal lines REL2. The second reset control signal terminals RE2 of the pixel circuits in a row of sub-pixels among the plurality of sub-pixels are coupled to one second reset control signal line REL2 among the plurality of second reset control signal lines REL2.

Exemplarily, as shown in FIG. 1, the pixel circuit includes a third reset control circuit 160. The third reset control circuit 160 is coupled to the light-emitting device L. The third reset control circuit 160 is configured to provide a signal at the second initialization signal terminal VINT2 to the light-emitting device L in response to a third reset control signal at the third reset control signal terminal RE3. Furthermore, the display area further includes a plurality of third reset control signal lines REL3. The third reset control signal terminals RE3 of the pixel circuits in a row of sub-pixels among the plurality of sub-pixels are coupled to one third reset control signal line REL3 among the plurality of third reset control signal lines REL3.

Exemplarily, as shown in FIG. 1, the pixel circuit further includes a first capacitor C1 and a second capacitor C2. A first end of the first capacitor C1 is coupled to the gate of the driving transistor M0. A second end of the first capacitor C1 is coupled to the second electrode of the driving transistor M0. A first end of the second capacitor C2 is coupled to the second electrode of the driving transistor M0. A second end of the second capacitor C2 is coupled to a fixed voltage terminal VG. Exemplarily, the fixed voltage terminal VG and the first power terminal ELVDD may be connected to the same signal. Of course, the fixed voltage terminal VG may also be connected to the same signal as one of the reference signal terminal VREF, the first initialization signal terminal, the second initialization signal terminal and the second power terminal ELVSS, which is not limited here.

In some embodiments of the present disclosure, the first power terminal ELVDD may be configured to load a constant first power voltage. The first power voltage is generally a positive value. Furthermore, the second power terminal ELVSS may be loaded with a constant second power voltage. The second power voltage may generally be a ground voltage or a negative value. In practical applications, specific values of the first power voltage and the second power voltage can be designed and determined according to the actual application environment and are not limited here.

In some embodiments of the present disclosure, as shown in FIG. 1, the driving transistor M0 can be set as an N-type transistor. The first electrode of the driving transistor M0 can be its drain. The second electrode of the driving transistor M0 can be its source. When the driving transistor M0 is in a saturation state, the current flows from the drain to the source of the driving transistor M0. Of course, the driving transistor M0 can also be set as a P-type transistor, which is not limited here.

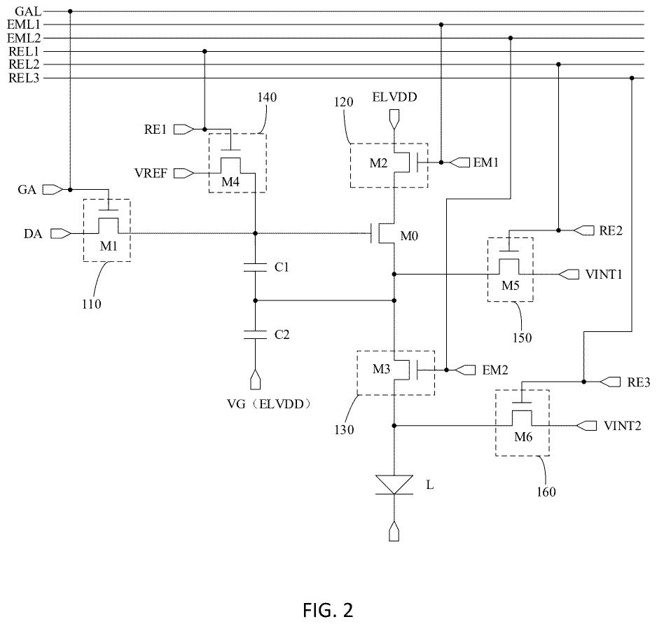

Exemplarily, as shown in FIG. 2, the data writing circuit 110 includes a data writing transistor M1. A gate of the data writing transistor M1 is coupled to the scan signal terminal GA, a first electrode of the data writing transistor M1 is coupled to the data signal terminal DA, and a second electrode of the data writing transistor M1 is coupled to the gate of the driving transistor M0.

Exemplarily, as shown in FIG. 2, the first light emitting control circuit 120 includes a first light emitting control transistor M2. A gate of the first light emitting control transistor M2 is coupled to the first light emitting control signal terminal EM1, a first electrode of the first light emitting control transistor M2 is coupled to the first power terminal ELVDD, and a second electrode of the first light emitting control transistor M2 is coupled to the first electrode of the driving transistor M0.

Exemplarily, as shown in FIG. 2, the second light emitting control circuit 130 includes a second light emitting control transistor M3. A gate of the second light emitting control transistor M3 is coupled to the second light emitting control signal terminal EM2, a first electrode of the second light emitting control transistor M3 is coupled to the second electrode of the driving transistor M0, and a second electrode of the first light emitting control transistor M2 is coupled to the anode of the light-emitting device L.

Exemplarily, as shown in FIG. 2, the first reset control circuit 140 includes a first reset control transistor M4. A gate of the first reset control transistor M4 is coupled to the first reset control signal terminal RE1, a first electrode of the first reset control transistor M4 is coupled to the reference signal terminal VREF, and a second electrode of the first reset control transistor M4 is coupled to the gate of the driving transistor M0.

Exemplarily, as shown in FIG. 2, the second reset control circuit 150 includes a second reset control transistor M5. A gate of the second reset control transistor M5 is coupled to the second reset control signal terminal RE2, a first electrode of the second reset control transistor M5 is coupled to the first initialization signal terminal, and a second electrode of the second reset control transistor M5 is coupled to the second electrode of the driving transistor M0.

Exemplarily, as shown in FIG. 2, the third reset control circuit 160 includes a third reset control transistor M6. A gate of the third reset control transistor M6 is coupled to the third reset control signal terminal RE3, the first electrode of the third reset control transistor M6 is coupled to the second initialization signal terminal, and the second electrode of the third reset control transistor M6 is coupled to the anode of the light-emitting device L.

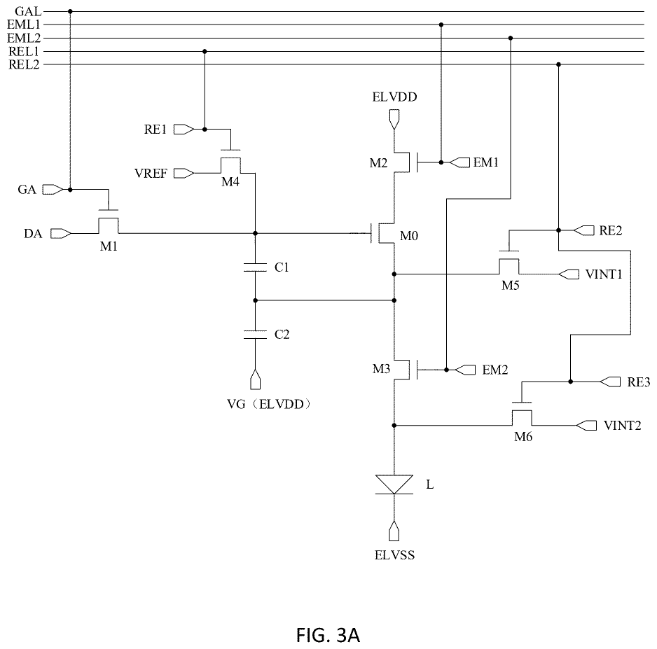

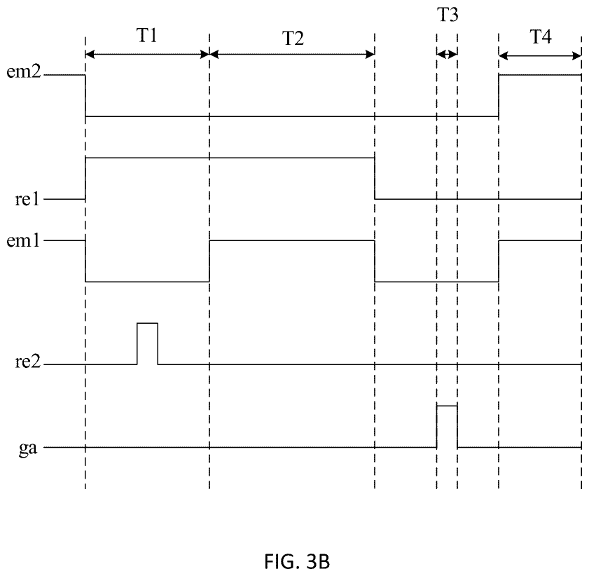

Further, as shown in FIG. 3A, the third reset control signal terminal RE3 and the second reset control signal terminal RE2 are connected to the same signal. The third reset control signal line REL3 and the second reset control signal line REL2 are the same signal line. In this way, the number of signal lines can be reduced, and there is no need to additionally provide a drive control circuit for inputting a signal to the third reset control signal terminal RE3, thereby further narrowing the bezel.

The timing diagram of signals corresponding to the pixel circuit shown in FIG. 3A is shown in FIG. 3B. Here, em1 represents the first light emitting control signal transmitted from the first light emitting control signal line EML1 to the first light emitting control signal terminal EM1, em2 represents the second light emitting control signal transmitted from the second light emitting control signal line EML2 to the second light emitting control signal terminal EM2, re1 represents the first reset control signal transmitted from the first reset control signal line REL1 to the first reset control signal terminal RE1, re2 represents the second reset control signal transmitted from the second reset control signal line REL2 to the second reset control signal terminal RE2, and ga represents the scan signal transmitted from the scan signal line GAL to the scan signal terminal GA. Furthermore, by inputting signals em1, em2, re1, re2 and ga into the pixel circuit respectively, the first light emitting control transistor M2, the second light emitting control transistor M3, the first reset control transistor M4, the second reset control transistor M5, the third reset control transistor M6 and the data writing transistor M1 can cooperate with each other to make the driving transistor M0 generate a driving current, and input the driving current into the light-emitting device L to drive the light-emitting device L to emit light.

Specifically, in the initialization stage T1, the first reset control transistor M4, the second reset control transistor M5 and the third reset control transistor M6 are all turned on, which can: provide the signal at the reference signal terminal VREF to the gate of the driving transistor M0 to reset the gate of the driving transistor M0, provide the signal at the first initialization signal terminal VINT1 to the second electrode of the driving transistor M0 to initialize the second electrode of the driving transistor M0, and provide the signal at the second initialization signal terminal VINT2 to the anode of the light-emitting device L to initialize the anode of the light-emitting device L.

In the threshold compensation stage T2, the first light emitting control transistor M2 and the first reset control transistor M4 are both turned on, which can provide the signal at the reference signal terminal VREF to the gate of the driving transistor M0, so that the potential of the gate of the driving transistor M0 is the potential Vref of the signal at the reference signal terminal VREF. Furthermore, a signal at the first power terminal ELVDD is input to the first electrode of the driving transistor M0, and the driving transistor M0 is turned on, so that the potential of the second electrode of the driving transistor M0 is Vref-Vth. Here, Vth is the threshold voltage of the driving transistor M0.

In the signal writing phase T3, the data writing transistor M1 is turned on, which can provide the data voltage at the data signal terminal DA to the gate of the driving transistor MO, so that the potential of the gate of the driving transistor M0 is the potential of the data voltage Vda. Through the action of the first capacitor C1 and the second capacitor C2, the potential of the second electrode of the driving transistor M0 changes to: Vref−Vth+c1(Vda−Vref)/(c1+c2). Here, c1 represents the capacitance value of the first capacitor C1, and c2 represents the capacitance value of the first capacitor C2.

In the light emitting stage T4, the first light emitting control transistor M2 and the second light emitting control transistor M3 are both turned on. The signal at the first power terminal ELVDD is input to the first electrode of the driving transistor M0. The driving transistor M0 generates a driving current IL, so that the potential of the second electrode of the driving transistor M0 changes to Vel. Then, through the action of the first capacitor C1 and the second capacitor C2, the potential of the gate of the driving transistor M0 changes to Vth+Vel+c2(Vda−Vref)/(c1+c2). Therefore, IL=K[Vel+c2(Vda−Vref)/(c1+c2)−Velvdd]². The driving current IL is input into the light-emitting device to drive the light-emitting device L to emit light.

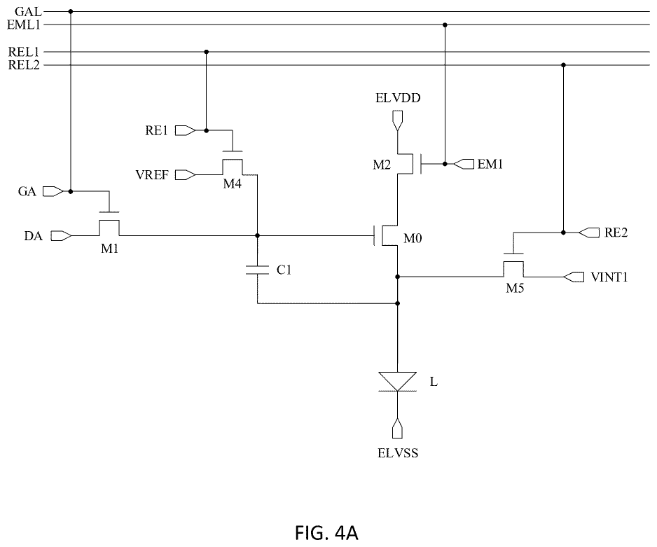

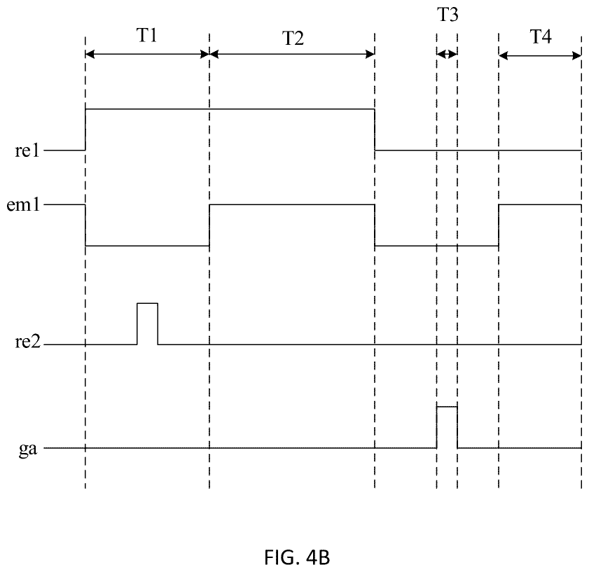

Further, as shown in FIG. 4A, the second capacitor C2, the second light emitting control transistor M3 and the third reset control transistor M6 may not be provided in the pixel circuit. This can reduce the area occupied by the pixel circuit and the number of signal lines, without the need for additional drive control circuits for inputting signals to the second light emitting control signal terminal EM2 and the third reset control signal terminal RE3, thereby further narrowing the bezel.

The timing diagram of signals corresponding to the pixel circuit shown in FIG. 4A is shown in FIG. 4B. Here, em1 represents the first light emitting control signal transmitted from the first light emitting control signal line EML1 to the first light emitting control signal terminal EM1, re1 represents the first reset control signal transmitted from the first reset control signal line REL1 to the first reset control signal terminal RE1, re2 represents the second reset control signal transmitted from the second reset control signal line REL2 to the second reset control signal terminal RE2, and ga represents the scan signal transmitted from the scan signal line GAL to the scan signal terminal GA. Furthermore, by inputting signals em1, re1, re2 and ga into the pixel circuit respectively, the first light emitting control transistor M2, the first reset control transistor M4, the second reset control transistor M5 and the data writing transistor M1 can cooperate with each other to make the driving transistor M0 generate a driving current, and input the driving current into the light-emitting device L to drive the light-emitting device L to emit light.

Specifically, in the initialization stage T1, the first reset control transistor M4 and the second reset control transistor M5 are both turned on, which can: provide the signal at the reference signal terminal VREF to the gate of the driving transistor M0 to reset the gate of the driving transistor M0, provide the signal at the first initialization signal terminal VINT1 to the second electrode of the driving transistor M0 to initialize the second electrode of the driving transistor M0, and provide the signal at the first initialization signal terminal VINT1 to the anode of the light-emitting device L to initialize the anode of the light-emitting device L.

In the threshold compensation stage T2, the first light emitting control transistor M2 and the first reset control transistor M4 are both turned on, which can provide the signal at the reference signal terminal VREF to the gate of the driving transistor M0, so that the potential of the gate of the driving transistor M0 is the potential Vref of the signal at the reference signal terminal VREF. Furthermore, a signal at the first power terminal ELVDD is input to the first electrode of the driving transistor M0, and the driving transistor M0 is turned on, so that the potential of the second electrode of the driving transistor M0 is Vref-Vth. Here, Vth is the threshold voltage of the driving transistor M0.

In the signal writing phase T3, the data writing transistor M1 is turned on, which can provide the data voltage at the data signal terminal DA to the gate of the driving transistor M0, so that the potential of the gate of the driving transistor M0 is the potential of the data voltage Vda. Through the action of the first capacitor C1 and the second capacitor C2, the potential of the second electrode of the driving transistor M0 changes to: Vref−Vth+c1(Vda−Vref)/(c1+coled). Here, c1 represents the capacitance value of the first capacitor C1, and coled represents the parasitic capacitance of the light-emitting device L.

In the light emitting stage T4, the first light emitting control transistor M2 and the second light emitting control transistor M3 are both turned on. The signal at the first power terminal ELVDD is input to the first electrode of the driving transistor M0. The driving transistor M0 generates a driving current IL, so that the potential of the second electrode of the driving transistor M0 changes to Vel. Then, through the action of the first capacitor C1 and the second capacitor C2, the potential of the gate of the driving transistor M0 changes to Vth+Vel+coled(Vda−Vref)/(c1+coled). Therefore, IL=K[Vel+coled(Vda−Vref)/(c1+coled)−Velvdd]². The driving current IL is input into the light-emitting device to drive the light-emitting device L to emit light.

In an implementation, the transistor may be an N-type transistor. Moreover, in an implementation, the first electrode of the transistor can be used as its source and the second electrode of the transistor can be used as its drain according to the type of the transistor and the signal at the gate of the transistor. Alternatively, the first electrode of the transistor can be used as its drain and the second electrode of the transistor can be used as its source. This can be designed and determined according to the actual application environment, and no specific distinction is made here.

It should be noted that the transistor in the embodiments of the present disclosure may be a thin film transistor (TFT) or a metal oxide semiconductor field effect transistor (MOS), which is not limited here.

The structure of each circuit in the pixel circuit provided in embodiments of the present disclosure is illustrated above in examples. In an implementation, the structure of the above circuit is not limited to the above structure provided in embodiments of the present disclosure, and can also be other structures known to those skilled in the art. These are all within the protection scope of the present disclosure and are not specifically limited here.

In practical applications, control signals need to be input into the above transistor by the shift register unit in the drive control circuit. The drive control circuit is usually arranged in the non-display area. The non-display area is usually also called the bezel area. If there are a large number of shift register units in the drive control circuit, a large area will be occupied, thereby causing the bezel area to occupy a larger area, which is not conducive to the narrow bezel design of the display panel. To this end, embodiments of the present disclosure provide a display panel to solve the problem that the drive control circuit occupies a large area, which is not conducive to the narrow bezel design of the display panel.

The display panel provided by the embodiments of the present disclosure is described below by taking the pixel circuit shown in FIG. 3A as an example. Embodiments of the present disclosure provide some pixel circuits. For example, the pixel circuit includes: a pixel control circuit configured to control the driving transistor M0 to generate a driving current that drives the light-emitting device L to emit light. Furthermore, the display area of the display panel includes a plurality of control signal lines. The pixel circuits in at least one row of sub-pixels among the plurality of sub-pixels are coupled to one of the plurality of control signal lines. The control signal lines corresponding to at least two adjacent rows of sub-pixels are coupled to each other. Furthermore, the non-display area includes a drive control circuit. The drive control circuit includes a plurality of shift register units. Control signal lines coupled to each other are coupled to one of the plurality of shift register units. The shift register unit is configured to transmit a signal to the pixel circuit via the control signal lines. With this arrangement, by coupling the control signal lines corresponding to at least two adjacent rows of sub-pixels to each other and then coupling the coupled control signal lines to a shift register unit, the number of shift register units can be reduced, the area occupied by the drive control circuit can be reduced, and the area occupied by the bezel area can be reduced, thereby enabling the display panel to achieve a narrow bezel design.

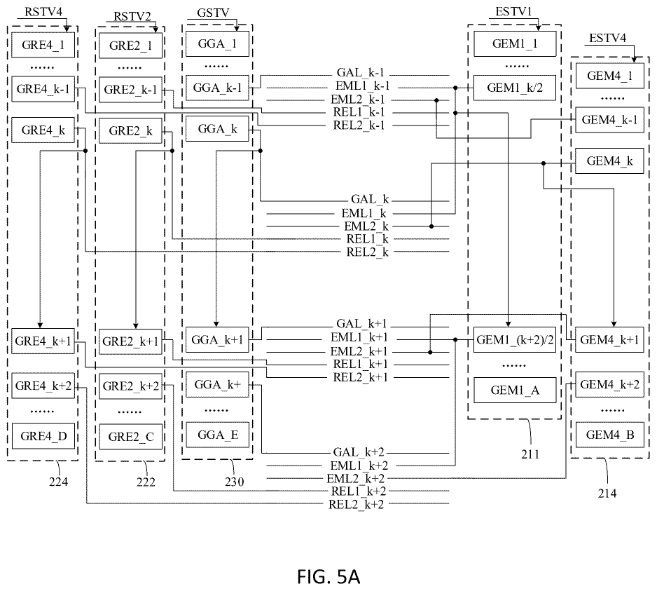

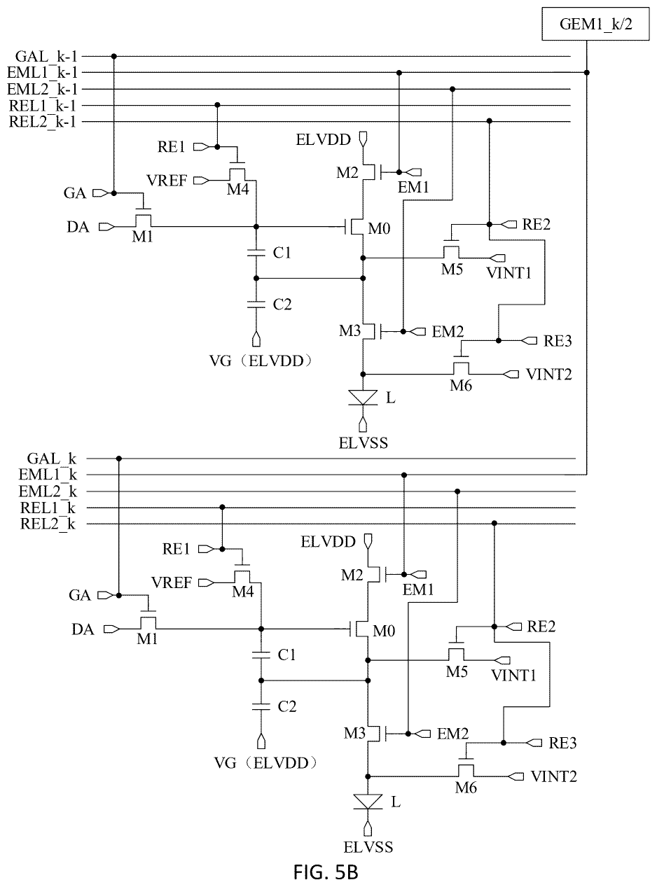

In some examples, in combination with FIG. 3A, FIG. 5A and FIG. 5B, the pixel control circuit can include a first light emitting control circuit 120 (i.e., a first light emitting control transistor M2). The drive control circuit includes a first light-emitting drive control circuit 211. The first light-emitting drive control circuit 211 includes a plurality of first light-emitting shift register units GEM1_1~GEM1_A (A is an integer greater than 0). The plurality of first light-emitting shift register units GEM1_1~GEM1_A can be cascaded. That is, the input signal terminal of the first-level first light-emitting shift register unit GEM1_1 among the plurality of first light-emitting shift register units GEM1_1^{~}GEM1_A is coupled to the first light-emitting trigger signal terminal ESTV1. The driving output terminal of the preceding-level first light-emitting shift register unit among the plurality of first light-emitting shift register units GEM1_1^{~}GEM1_A is coupled to the input signal terminal of the following-level first light-emitting shift register unit. For example, the driving output terminal of the first light-emitting shift register unit GEM1_k/2 is coupled to the input signal terminal of the first light-emitting shift register unit GEM1_(k+2)/2.

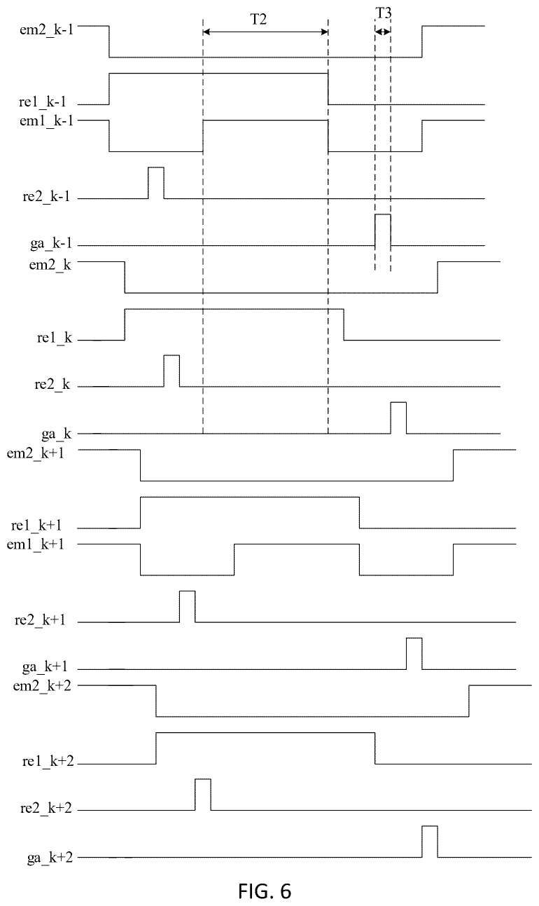

Furthermore, the shift register unit includes a first light-emitting shift register unit, and the control signal line includes a first light emitting control signal line EML1. Furthermore, the first light emitting control signal lines EML1 corresponding to at least two adjacent rows of sub-pixels are coupled to each other and then coupled to one first light-emitting shift register unit among the plurality of first light-emitting shift register units. With this arrangement, the number of first light-emitting shift register units can be reduced, thereby reducing the occupied area of the bezel area, thereby enabling the display panel to achieve a narrow bezel design. Exemplarily, the first light emitting control signal lines EML1 corresponding to two adjacent rows of sub-pixels may be coupled to each other and then coupled to one first light-emitting shift register unit among the plurality of first light-emitting shift register units. For example, as shown in FIGS. 5A, 5B and 6, the first light emitting control signal line EML1_k−1 corresponding to the sub-pixels in the k-1^{th} row and the first light emitting control signal line EML1_k corresponding to the sub-pixels in the k^{th} row are coupled to each other and then coupled to the driving output terminal of the first light-emitting shift register unit GEM1_k/2. The first light emitting control signal em1_k−1 is input to the first light emitting control signal line EML1_k−1 and the first light emitting control signal line EML1_k through the first light-emitting shift register unit GEM1_k/2. In addition, the first light emitting control signal line EML1_k+1 corresponding to the sub-pixels in the k+1^{th} row and the first light emitting control signal line EML1_k+2 corresponding to the sub-pixels in the k+2^{th} row are coupled to each other and then coupled to the driving output terminal of the first light-emitting shift register unit GEM1_(k+2)/2. The first light emitting control signal em1_k+1 is input to the first light emitting control signal line EML1_k+1 and the first light emitting control signal line EML1_k+2 through the first light-emitting shift register unit GEM1_(k+2)/2. With this arrangement, the number of first light-emitting shift register units can be reduced by half. Of course, in practical applications, the first light emitting control signal lines EML1 corresponding to three, four or more adjacent rows of sub-pixels may be coupled to each other and then coupled to one first light-emitting shift register unit, which is not limited here.

It should be noted that, taking the k^{th} row of sub-pixels as an example, in the threshold compensation stage T2, the first light emitting control transistor M2 and the first reset control transistor M4 are both turned on, that is, the signals em1_k and re1_k are both valid signals (for example, high level) at this stage. In the signal writing stage T3, that is, after the threshold compensation stage T2, the signal ga_k is a valid signal (for example, high level), and the data writing transistor M1 is turned on. Therefore, the compensation time of the threshold voltage is determined by the time period between the rising edge of the signal em1_k and the falling edge of the signal re1_k. Therefore, if the rising edge of re1_k+n corresponding to the sub-pixels in the k+n^{th} row is before the falling edge of em1_k corresponding to the sub-pixels in the k^{th} row, but does not affect the normal operation of other timing sequences, the first light emitting control signal lines EML1 corresponding to the sub-pixels in the k^{th} row to the k+n^{th} row can all be electrically connected to each other, n is an integer greater than or equal to 2.

In an implementation, as shown in FIG. 5A and FIG. 5B, the non-display area further includes a fourth light-emitting drive control circuit 214. The fourth light-emitting drive control circuit 214 includes a plurality of fourth light-emitting shift register units GEM4_1^{~}GEM4_B (B is an integer greater than 0). The plurality of fourth light-emitting shift register units GEM4_1^{~}GEM4_B can be cascaded. That is, the input signal terminal of the first-level fourth light-emitting shift register unit GEM4_1 among the plurality of fourth light-emitting shift register units GEM4_1^{~}GEM4_B is coupled to the fourth light-emitting trigger signal terminal ESTV4. The driving output terminal of the preceding-level fourth light-emitting shift register unit among the plurality of fourth light-emitting shift register units GEM4_1^{~}GEM4 B is coupled to the input signal terminal of the following-level fourth light-emitting shift register unit. For example, the driving output terminal of the fourth light-emitting shift register unit GEM4_k is coupled to the input signal terminal of the fourth light-emitting shift register unit GEM4_k+1.

Furthermore, the second light emitting control signal line EML2 corresponding to each row of sub-pixels is coupled to one fourth light-emitting shift register unit among the plurality of fourth light-emitting shift register units. For example, in combination of FIGS. 5A, 5B and 6, the fourth light-emitting shift register unit GEM4_k−1 is coupled to the driving output terminal of the second light emitting control signal line EML2_k−1 corresponding to the sub-pixels in the k-1^{th} row. The second light emitting control signal em2_k−1 is input to the second light emitting control signal line EML2_k-1 through the fourth light-emitting shift register unit GEM4_k−1. A driving output terminal of the fourth light-emitting shift register unit GEM4_k is coupled to the second light emitting control signal line EML2_k corresponding to the sub-pixels in the k^{th} row. The second light emitting control signal em2_k is input to the second light emitting control signal line EML2_k through the fourth light-emitting shift register unit GEM4_k. The driving output terminal of the fourth light-emitting shift register unit GEM4_k+1 is coupled to the second light emitting control signal line EML2_k+1 corresponding to the sub-pixels in the k+1th row. The second light emitting control signal em2_k+1 is input to the second light emitting control signal line EML2_k+1 through the fourth light-emitting shift register unit GEM4_k+1.

The driving output terminal of the fourth light-emitting shift register unit GEM4_k+2 is coupled to the second light emitting control signal line EML2_k+2 corresponding to the sub-pixels in the k+2^{th} row. The second light emitting control signal em2_k+2 is input to the second light emitting control signal line EML2_k+2 through the fourth light-emitting shift register unit GEM4_k+2.

In an implementation, as shown in FIGS. 5A and 5B, the non-display area also includes a second reset drive control circuit 222. The second reset drive control circuit 222 includes a plurality of second reset shift register units GRE2_1^{~}GRE2_C. The plurality of second reset shift register units GRE2_1^{~}GRE2_C can be cascaded. That is, the input signal terminal of the first-level second reset shift register unit GRE2_1 among the plurality of second reset shift register units GRE2_1^{~}GRE2_C is coupled to the second reset trigger signal terminal RSTV2. The driving output terminal of the preceding-level second reset shift register unit among the plurality of second reset shift register units GRE2_1^{~}GRE2_C is coupled to the input signal terminal of the following-level second reset shift register unit. For example, the driving output terminal of the second reset shift register unit GRE2_k is coupled to the input signal terminal of the second reset shift register unit GRE2_k+1.

Furthermore, the first reset control signal line REL1 corresponding to each row of sub-pixels is coupled to one second reset shift register unit among the plurality of second reset shift register units. For example, in combination with FIGS. 5A, 5B and 6, the driving output terminal of the second reset shift register unit GRE2_k−1 is coupled to the first reset control signal line REL1_k−1. The first reset control signal re1_k−1 is input to the first reset control signal line REL1_k−1 through the second reset shift register unit GRE2_k−1. The driving output terminal of the second reset shift register unit GRE2_k is coupled to the first reset control signal line REL1_k. The first reset control signal re1_k is input to the first reset control signal line REL1_k through the second reset shift register unit GRE2_k. The driving output terminal of the second reset shift register unit GRE2_k+1 is coupled to the first reset control signal line REL1_k+1. The first reset control signal re1_k+1 is input to the first reset control signal line REL1_k+1 through the second reset shift register unit GRE2_k+1. The driving output terminal of the second reset shift register unit GRE2_k+2 is coupled to the first reset control signal line REL1_k+2. The first reset control signal re1_k+2 is input to the first reset control signal line REL1_k+2 through the second reset shift register unit GRE2_k+2.

In an implementation, as shown in FIGS. 5A and 5B, the non-display area also includes a fourth reset drive control circuit 224. The fourth reset drive control circuit 224 includes a plurality of fourth reset shift register units GRE4_1^{~}GRE4_D. The plurality of fourth reset shift register units GRE4_1^{~}GRE4_D can be cascaded. That is, the input signal terminal of the first-level fourth reset shift register unit GRE4_1 among the plurality of fourth reset shift register units GRE4_1^{~}GRE4_D is coupled to the fourth reset trigger signal terminal RSTV4. The driving output terminal of the preceding-level fourth reset shift register unit among the plurality of fourth reset shift register units GRE4_1^{~}GRE4_D is coupled to the input signal terminal of the following-level fourth reset shift register unit. For example, the driving output terminal of the fourth reset shift register unit GRE4_k is coupled to the input signal terminal of the fourth reset shift register unit GRE4_k+1.

Furthermore, the second reset control signal line REL2 corresponding to each row of sub-pixels is coupled to one fourth reset shift register unit among the plurality of fourth reset shift register units. For example, in combination with FIGS. 5A, 5B and 6, the driving output terminal of the fourth reset shift register unit GRE4_k−1 is coupled to the second reset control signal line REL2_k−1. The second reset control signal re2_k−1 is input to the second reset control signal line REL2_k−1 through the fourth reset shift register unit GRE4_k−1. The driving output terminal of the fourth reset shift register unit GRE4_k is coupled to the second reset control signal line REL2_k. The second reset control signal re2_k is input to the second reset control signal line REL2_k through the fourth reset shift register unit GRE4_k. The driving output terminal of the fourth reset shift register unit GRE4_k+1 is coupled to the second reset control signal line REL2_k+1. The second reset control signal re2_k+1 is input to the second reset control signal line REL2_k+1 through the fourth reset shift register unit GRE4_k+1. The driving output terminal of the fourth reset shift register unit GRE4_k+2 is coupled to the second reset control signal line REL2_k+2. The second reset control signal re2_k+2 is input to the second reset control signal line REL2_k+2 through the fourth reset shift register unit GRE4_k+2.

In an implementation, as shown in FIGS. 5A and 5B, the non-display area also includes a scan control circuit 230. The scan control circuit 230 includes a plurality of scan shift register units GGA_1^{~}GGA_E. The scan signal line GAL corresponding to each row of sub-pixels is coupled to one scan shift register unit among the plurality of scan shift register units. For example, in combination with FIG. 5A, FIG. 5B and FIG. 6, the driving output terminal of the scan shift register unit GGA_k-1 is coupled to the scan signal line GAL_k−1. The scan signal ga_k−1 is input to the scan signal line GAL_k−1 through the scan shift register unit GGA_k−1. The driving output terminal of the scan shift register unit GGA_k is coupled to the scan signal line GAL_k. The scan signal ga_k is input to the scan signal line GAL_k through the scan shift register unit GGA_k. The driving output terminal of the scan shift register unit GGA_k+1 is coupled to the scan signal line GAL_k+1. The scan signal ga_k+1 is input to the scan control signal line GAL_k+1 through the scan shift register unit GGA_k+1. The driving output terminal of the scan shift register unit GGA_k+2 is coupled to the scan control signal line GAL_k+2. The scan signal ga_k+2 is input to the scan control signal line GAL_k+2 through the scan shift register unit GGA_k+2.

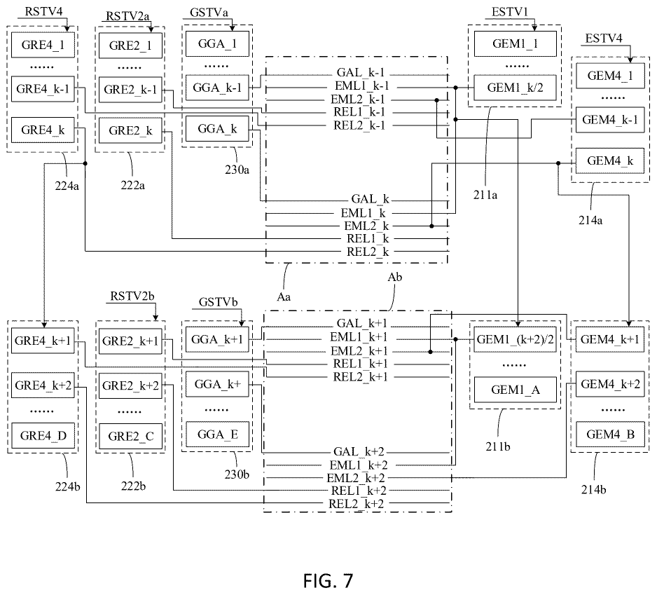

In practical applications, the display panel may operate at various refresh frequencies, for example, 1 Hz, 60 Hz, 90 Hz, and 120 Hz. Moreover, with the development of technology, display solutions that support different refresh frequencies in different regions have emerged. In an implementation, the display area includes a plurality of display sub-areas. The plurality of display sub-areas are arranged along a column direction of sub-pixels. The refresh frequencies of any two of the plurality of display sub-areas may be the same or different. For example, as shown in FIG. 7, the display area is divided into two display sub-areas Aa and Ab. The refresh frequency corresponding to the display sub-area Aa can be set to 60 Hz, and the refresh frequency corresponding to the display sub-area Ab can be set to 1 Hz. Alternatively, the refresh frequency corresponding to the display sub-area Aa can be set to 1 Hz, and the refresh frequency corresponding to the display sub-area Ab can be set to 60 Hz.

In some embodiments, the plurality of first light-emitting shift register units may belong to a plurality of first light-emitting register groups. The plurality of first light-emitting register groups correspond one-to-one to the plurality of display sub-areas. The plurality of first light-emitting register groups are coupled to the first light emitting control signal lines in the corresponding display sub-areas. Furthermore, the plurality of first light-emitting register groups correspond to a first light-emitting trigger signal terminal. The input signal terminal of the first-level first light-emitting shift register unit in the first-level first light-emitting register group of the plurality of first light-emitting register groups is coupled to the first light-emitting trigger signal terminal. The driving output terminal of the last-level first light-emitting shift register unit of the preceding-level first light-emitting register group in two adjacent first light-emitting register groups is coupled to the input signal terminal of the first-level first light-emitting shift register unit of the following-level first light-emitting register group. For example, as shown in FIG. 7, taking the display area including two display sub-areas Aa and Ab as an example, the display sub-area Aa corresponds to the first light-emitting register group 211a. The first light-emitting register group 211a includes the first-level first light-emitting shift register unit GEM1_1 to the k/2-level first light-emitting shift register unit GEM1_k/2. The input signal terminal of the first-level first light-emitting shift register unit GEM1_1 is coupled to the first light-emitting trigger signal terminal ESTV1. The driving output terminal of the preceding-level first light-emitting shift register unit is coupled to the input signal terminal of the following-level first light-emitting shift register unit in the first-level first light-emitting shift register unit GEM1_1 to the k/2-level first light-emitting shift register unit GEM1_k/2. Furthermore, the display sub-area Ab corresponds to the first light-emitting register group 211b. The first light-emitting register group 211b includes the first-level first light-emitting shift register unit GEM1_(k+2)/2 to the A-level first light-emitting shift register unit GEM1_A. The driving output terminal of the preceding-level first light-emitting shift register unit is coupled to the input signal terminal of the following-level first light-emitting shift register unit in the first-level first light-emitting shift register unit GEM1_(k+2)/2 to the A-level first light-emitting shift register unit GEM1_A. The driving output terminal of the k/2-level first light-emitting shift register unit GEM1_k/2 in the display sub-area Aa is coupled to the input signal terminal of the first-level first light-emitting shift register unit GEM1_(k+2)/2 in the display sub-area Ab.

Of course, the plurality of first light-emitting register groups may correspond one-to-one to a plurality of first light-emitting trigger signal terminals. The input signal terminal of the first-level first light-emitting shift register unit in the first light-emitting register group may be coupled to the corresponding first light-emitting trigger signal terminal. Furthermore, the first light-emitting shift register units in the same first light-emitting register group are cascaded.

In some embodiments, the plurality of fourth light-emitting shift register units can belong to a plurality of fourth light-emitting register groups. The plurality of fourth light-emitting register groups correspond one-to-one to the plurality of display sub-areas. The plurality of fourth light-emitting register groups are coupled to the second light emitting control signal lines in the corresponding display sub-areas. The plurality of fourth light-emitting register groups correspond to a fourth light-emitting trigger signal terminal. The input signal terminal of the first-level fourth light-emitting shift register unit in the first-level fourth light-emitting register group of the plurality of fourth light-emitting register groups is coupled to the fourth light-emitting trigger signal terminal. The driving output terminal of the last-level fourth light-emitting shift register unit of the preceding-level fourth light-emitting register group of two adjacent fourth light-emitting register groups is coupled to the input signal terminal of the first-level fourth light-emitting shift register unit of the following-level fourth light-emitting register group. For example, as shown in FIG. 7, taking the display area including two display sub-areas Aa and Ab as an example, the display sub-area Aa corresponds to the fourth light-emitting register group 214a. The fourth light-emitting register group 214a includes the first-level fourth light-emitting shift register unit GEM4_1 to the k-level fourth light-emitting shift register unit GEM4_k. The input signal terminal of the first-level fourth light-emitting shift register unit GEM4_1 is coupled to the fourth light-emitting trigger signal terminal ESTV4. The driving output terminal of the preceding-level fourth light-emitting shift register unit among the first-level fourth light-emitting shift register unit GEM4_1 to the k-level fourth light-emitting shift register unit GEM4_k is coupled to the input signal terminal of the following-level fourth light-emitting shift register unit. Furthermore, the display sub-area Ab corresponds to the fourth light-emitting register group 214b. The fourth light-emitting register group 214b includes the first-level fourth light-emitting shift register unit GEM4_k+1 to the B-level fourth light-emitting shift register unit GEM4_B. The driving output terminal of the preceding-level fourth light-emitting shift register unit among the first-level fourth light-emitting shift register unit GEM4_k+1 to the B-level fourth light-emitting shift register unit GEM4_B is coupled to the input signal terminal of the following-level fourth light-emitting shift register unit.

Of course, the plurality of fourth light-emitting register groups can also correspond one-to-one to a plurality of fourth light-emitting trigger signal terminals. The input signal terminal of the first-level fourth light-emitting shift register unit in the fourth light-emitting register group is coupled to the corresponding fourth light-emitting trigger signal terminal.

In some embodiments, the plurality of second reset shift register units may belong to a plurality of second reset register groups. The plurality of second reset register groups correspond one-to-one to the plurality of display sub-areas. The plurality of second reset register groups are coupled to the first reset control signal lines in the corresponding display sub-areas. Furthermore, the plurality of second reset register groups correspond one-to-one to a plurality of second reset trigger signal terminals. The input signal terminal of the first-level second reset shift register unit in the second reset register group is coupled to the corresponding second reset trigger signal terminal. For example, as shown in FIG. 7, taking the display area including two display sub-areas Aa and Ab as an example, the display sub-area Aa corresponds to the second reset register group 222a. The second reset register group 222a includes the first-level second reset shift register unit GRE2_1 to the k-level second reset shift register unit GRE2_k. The input signal terminal of the first-level second reset shift register unit GRE2_1 is coupled to the second reset trigger signal terminal RSTV2a. The driving output terminal of the preceding-level second reset shift register unit among the first-level second reset shift register unit GRE2_1 to the k-level second reset shift register unit GRE2_k is coupled to the input signal terminal of the following-level second reset shift register unit. Furthermore, the display sub-area Ab corresponds to the second reset register group 222b. The second reset register group 222b includes the first-level second reset shift register unit GRE2_k+1 to the C-level second reset shift register unit GRE2_C. The input signal terminal of the first-level second reset shift register unit GRE2_k+1 is coupled to the second reset trigger signal terminal RSTV2b. The driving output terminal of the preceding-level second reset shift register unit among the first-level second reset shift register unit GRE2_k+1 to the C-level second reset shift register unit GRE2_C is coupled to the input signal terminal of the following-level second reset shift register unit.

Of course, the plurality of second reset register groups can also correspond to one second reset trigger signal terminal. The input signal terminal of the first-level second reset shift register unit in the first-level second reset register group among the plurality of second reset register groups is coupled to the second reset trigger signal terminal. The driving output terminal of the last-level second reset shift register unit of the preceding-level second reset register group in two adjacent second reset register groups is coupled to the input signal terminal of the first-level second reset shift register unit of the following-level second reset register group.

In some embodiments, the plurality of scan shift register units may belong to a plurality of scan register groups. The plurality of scan register groups correspond one-to one to the plurality of display sub-areas. The plurality of scan register groups are coupled to the scan signal lines in the corresponding display sub-areas. Furthermore, the plurality of scan register groups correspond one-to one to a plurality of scan trigger signal terminals. The input signal terminal of the first-level scan shift register unit in the scan register group is coupled to the corresponding scan trigger signal terminal. For example, as shown in FIG. 7, taking the display area including two display sub-areas Aa and Ab as an example, the display sub-area Aa corresponds to the scan register group 230a. The scan register group 230a includes the first-level scan shift register unit GGA_1 to the k-level scan shift register unit GGA_k. The input signal terminal of the first-level scan shift register unit GGA_1 is coupled to the scan trigger signal terminal GSTVa. The driving output terminal of the preceding-level scan shift register unit among the first-level scan shift register unit GGA_1 to the k-level scan shift register unit GGA_k is coupled to the input signal terminal of the following-level scan shift register unit.

Furthermore, the display sub-area Ab corresponds to the scan register group 230b. The scan register group 230b includes a first-level scan shift register unit GGA_k+1 to an E-level scan shift register unit GGA_E. The input signal terminal of the first-level scan shift register unit GGA_k+1 is coupled to the scan trigger signal terminal GSTVb. The driving output terminal of the preceding-level scan shift register unit among the first-level scan shift register unit GGA_k+1 to the E-level scan shift register unit GGA_E is coupled to the input signal terminal of the following-level scan shift register unit.

In some embodiments, the plurality of fourth reset shift register units may belong to a plurality of fourth reset register groups. The plurality of fourth reset register groups correspond one-to-one to the plurality of display sub-areas. The plurality of fourth reset register groups are coupled to the second reset control signal lines in the corresponding display sub-areas. Furthermore, the plurality of fourth reset register groups correspond to one fourth reset trigger signal terminal. The input signal terminal of the first-level fourth reset shift register unit in the first-level fourth reset register group among the plurality of fourth reset register groups is coupled to the fourth reset trigger signal terminal. The driving output terminal of the last-level fourth reset shift register unit of the preceding-level fourth reset register group in two adjacent fourth reset register groups is coupled to the input signal terminal of the first-level fourth reset shift register unit of the following-level fourth reset register group. For example, as shown in FIG. 7, taking the display area including two display sub-areas Aa and Ab as an example, the display sub-area Aa corresponds to the fourth reset register group 224a. The fourth reset register group 224a includes the first-level fourth reset shift register unit GRE4_1 to the k-level fourth reset shift register unit GRE4_k. The input signal terminal of the first-level fourth reset shift register unit GRE4_1 is coupled to the fourth reset trigger signal terminal RSTV4. The driving output terminal of the preceding-level fourth reset shift register unit among the first-level fourth reset shift register unit GRE4_1 to the k-level fourth reset shift register unit GRE4_k is coupled to the input signal terminal of the following-level level fourth reset shift register unit. Furthermore, the display sub-area Ab corresponds to the fourth reset register group 224b. The fourth reset register group 224b includes the first-level fourth reset shift register unit GRE4_k+1 to the D-level fourth reset shift register unit GRE4_D. The driving output terminal of the preceding-level fourth reset shift register unit among the first-level fourth reset shift register unit GRE4_k+1 to the D-level fourth reset shift register unit GRE4_D is coupled to the input signal terminal of the following-level fourth reset shift register unit. The input signal terminal of the first-level fourth reset shift register unit GRE4_k+1 in the fourth reset register group 224b is coupled to the driving output terminal of the k-level fourth reset shift register unit GRE4_k in the fourth reset register group 224a.

Of course, the plurality of fourth reset register groups may correspond one-to-one to a plurality of fourth reset trigger signal terminals. The input signal terminal of the first-level fourth reset shift register unit in the fourth reset register group may be coupled to the corresponding fourth reset trigger signal terminal.

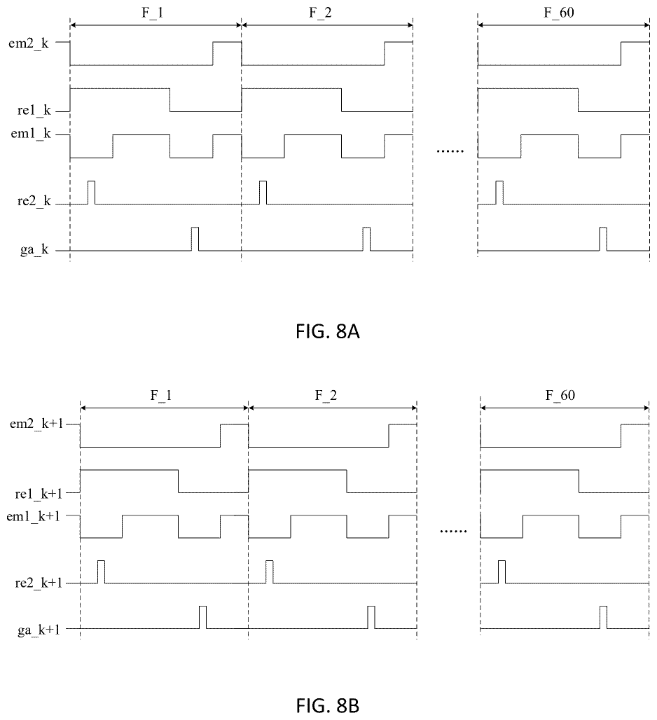

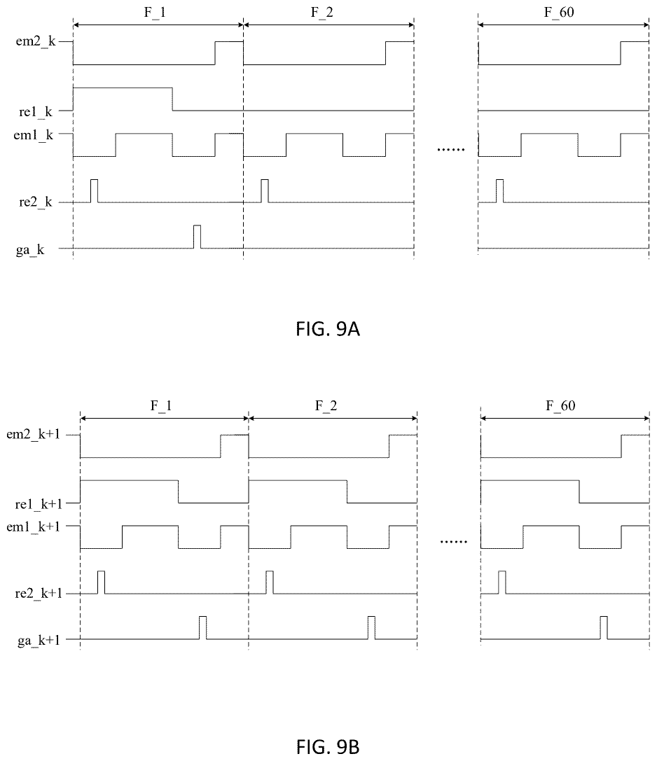

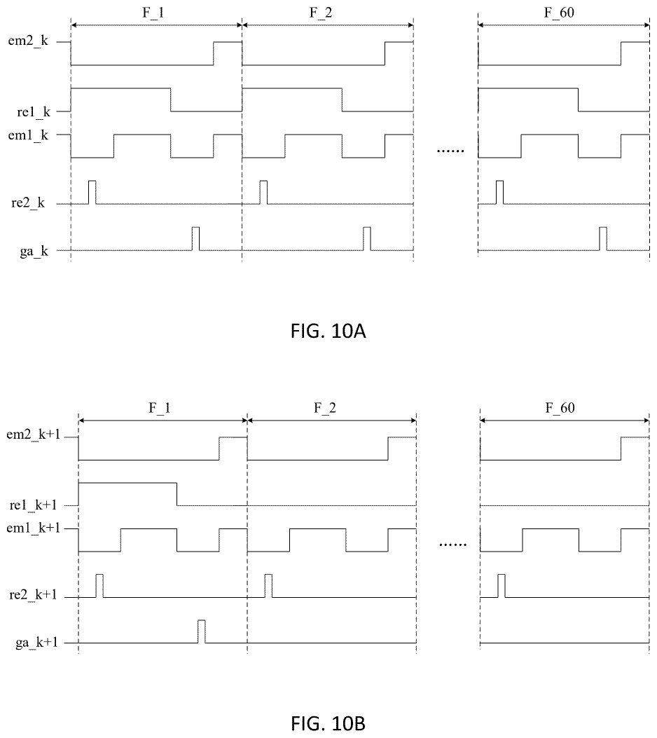

The structure of the display panel shown in FIG. 7 is taken as an example below. The working process of the display panel in the embodiments of the present disclosure is described in combination with FIG. 8A to FIG. 10B. In FIGS. 8A, 8B, 9B and 10A, F_1^{~}F_60 respectively represent display frames in 1 second. In FIGS. 9A and 10B, F_1 represents a display frame in 1 second, and F_2^{~}F_60 respectively represent hold frames in 1 second.

In combination with FIGS. 8A and 8B, the refresh frequencies of the display sub-area Aa and the display sub-area Ab can be the same. For example, the refresh frequencies of the display sub-area Aa and the display sub-area Ab are both 60 Hz. Furthermore, by controlling the first light-emitting register group 211a and the first light-emitting register group 211b to operate, the first light emitting control signal em1_k can be input to the first light emitting control signal line EML1_k, and the first light emitting control signal em1_k+1 can be input to the first light emitting control signal line EML1_k+1. By controlling the fourth light-emitting register group 214a and the fourth light-emitting register group 214b to operate, the second light emitting control signal em2_k can be input to the second light emitting control signal line EML2_k, and the second light emitting control signal em2_k+1 can be input to the second light emitting control signal line EML2_k+1. By controlling the second reset register group 222a and the second reset register group 222b to operate, the first reset control signal re1_k can be input to the first reset control signal line REL1_k, and the first reset control signal re1_k+1 can be input to the first reset control signal line REL1_k+1. By controlling the fourth reset register group 224a and the fourth reset register group 224b to operate, the second reset control signal re2_k can be input to the second reset control signal line REL2_k, and the second reset control signal re2_k+1 can be input to the second reset control signal line REL2_k+1. By controlling the scan register group 230a and the scan register group 230b to operate, the scan signal ga_k can be input to the scan signal line GAL_k, and the scan signal ga_k+1 can be input to the scan signal line GAL_k+1.

In combination with FIGS. 9A and 9B, the refresh frequency of the display sub-area Aa can be lower than the refresh frequency of the display sub-area Ab. For example, the refresh frequency of the display sub-area Aa is 1 Hz, and the refresh frequency of the display sub-area Ab is 60 Hz. Furthermore, by controlling the first light-emitting register group 211a and the first light-emitting register group 211b to operate, the first light emitting control signal em1_k can be input to the first light emitting control signal line EML1_k, and the first light emitting control signal em1_k+1 can be input to the first light emitting control signal line EML1_k+1. By controlling the fourth light-emitting register group 214a and the fourth light-emitting register group 214b to operate, the second light emitting control signal em2_k can be input to the second light emitting control signal line EML2_k, and the second light emitting control signal em2_k+1 can be input to the second light emitting control signal line EML2_k+1. By controlling the second reset register group 222a and the second reset register group 222b to operate, the first reset control signal re1_k can be input to the first reset control signal line REL1_k, and the first reset control signal re1_k+1 can be input to the first reset control signal line REL1_k+1. By controlling the fourth reset register group 224a and the fourth reset register group 224b to operate, the second reset control signal re2_k can be input to the second reset control signal line REL2_k, and the second reset control signal re2_k+1 can be input to the second reset control signal line REL2_k+1. By controlling the scan register group 230a and the scan register group 230b to operate, the scan signal ga_k can be input to the scan signal line GAL_k, and the scan signal ga_k+1 can be input to the scan signal line GAL_k+1.

In combination with FIGS. 10A and 10B, the refresh frequency of the display sub-area Aa can be greater than the refresh frequency of the display sub-area Ab. For example, the refresh frequency of the display sub-area Aa is 60 Hz, and the refresh frequency of the display sub-area Ab is 1 Hz. Furthermore, by controlling the first light-emitting register group 211a and the first light-emitting register group 211b to operate, the first light emitting control signal em1_k can be input to the first light emitting control signal line EML1_k, and the first light emitting control signal em1_k+1 can be input to the first light emitting control signal line EML1_k+1. By controlling the fourth light-emitting register group 214a and the fourth light-emitting register group 214b to operate, the second light emitting control signal em2_k can be input to the second light emitting control signal line EML2_k, and the second light emitting control signal em2_k+1 can be input to the second light emitting control signal line EML2_k+1. By controlling the second reset register group 222a and the second reset register group 222b to operate, the first reset control signal re1_k can be input to the first reset control signal line REL1_k, and the first reset control signal re1_k+1 can be input to the first reset control signal line REL1_k+1. By controlling the fourth reset register group 224a and the fourth reset register group 224 to operate, the second reset control signal re2_k can be input to the second reset control signal line REL2_k, and the second reset control signal re2_k+1 can be input to the second reset control signal line REL2_k+1. By controlling the scan register group 230a and the scan register group 230b to operate, the scan signal ga_k can be input to the scan signal line GAL_k, and the scan signal ga_k+1 can be input to the scan signal line GAL_k+1.

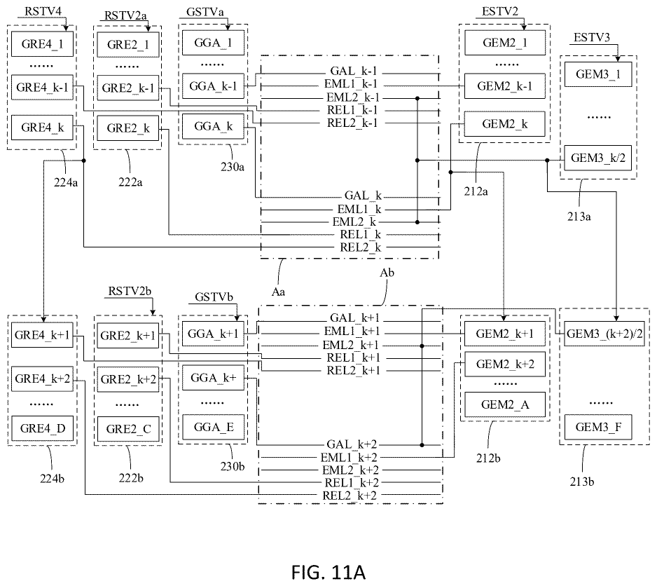

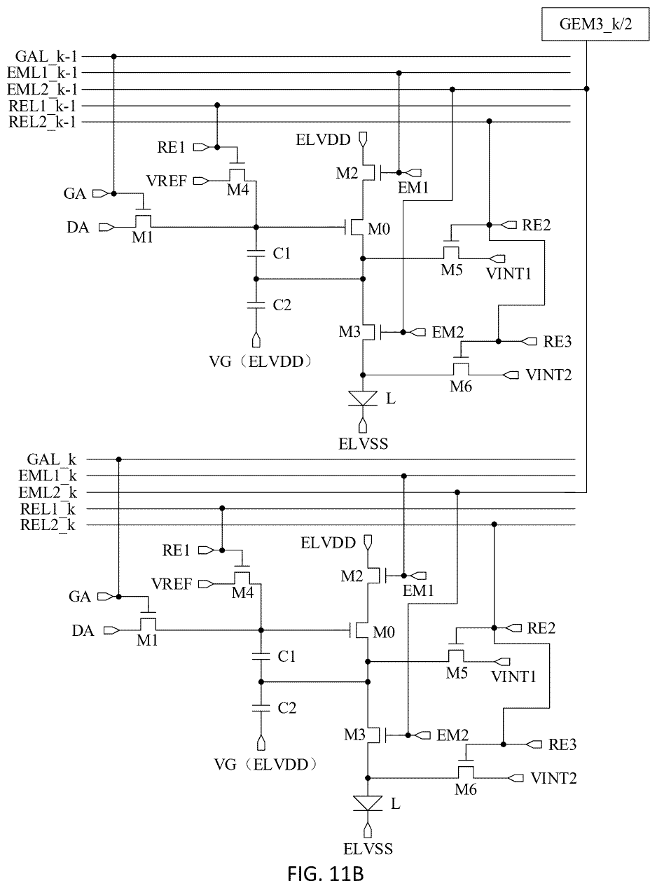

Embodiments of the present disclosure provide some further structural schematic diagrams of display panels. As shown in FIG. 11A, the implementation methods in the above embodiments are modified. Only the differences between these embodiments and the above-mentioned embodiments are described below, and the similarities are not repeated here.

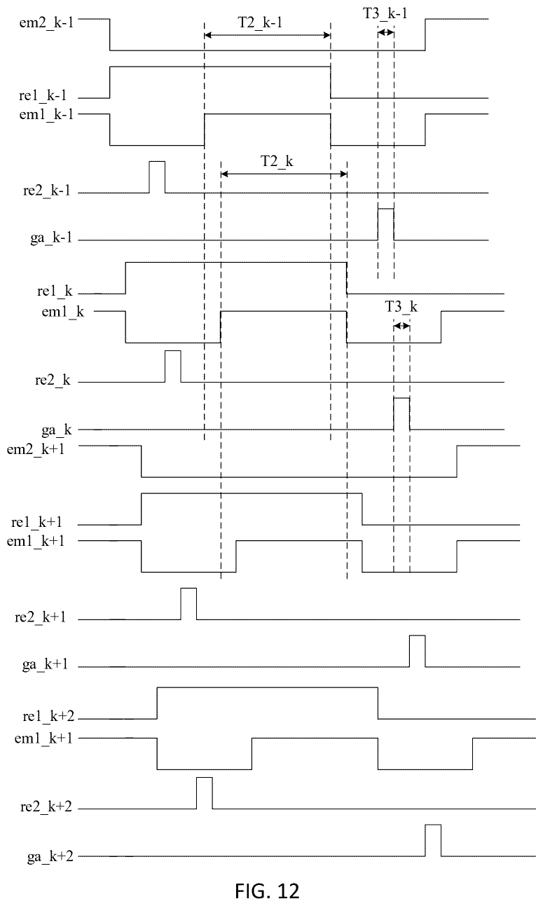

In embodiments of the present disclosure, as shown in FIGS. 11A and 11B, the pixel control circuit includes a second light emitting control circuit 130. The drive control circuit includes a third light-emitting drive control circuit. The third light-emitting drive control circuit includes a plurality of third light-emitting shift register units GEM3_1^{~}GEM3_F (F is an integer greater than 0). The plurality of third light-emitting shift register units GEM3_1^{~}GEM3_F can be cascaded. The shift register unit includes a third light-emitting shift register unit. Furthermore, the control signal line comprises a second light emitting control signal line EML2. The second light emitting control signal lines EML2 corresponding to two adjacent rows of sub-pixels are coupled with each other and then coupled to one third light-emitting shift register unit among the plurality of third light-emitting shift register units. For example, as shown in FIGS. 11A to 12, the second light emitting control signal line EML2_k−1 corresponding to the sub-pixels in the k−1^{th} row and the second light emitting control signal line EML2_k corresponding to the sub-pixels in the k^{th} row are coupled to each other and then coupled to the driving output terminal of the third light-emitting shift register unit GEM3_k/2. The second light emitting control signal em2_k−1 is input to the second light emitting control signal line EML2_k−1 and the second light emitting control signal line EML2_k through the third light-emitting shift register unit GEM3_k/2. In addition, the second light emitting control signal line EML2_k+1 corresponding to the sub-pixels in the k+1th row and the second light emitting control signal line EML2_k+2 corresponding to the sub-pixels in the k+2^{th} row are coupled to each other and then coupled to the driving output terminal of the third light-emitting shift register unit GEM3_(k+2)/2. The second light emitting control signal em2_k+1 is input to the second light emitting control signal line EML2_k+1 and the second light emitting control signal line EML2_k+2 through the third light-emitting shift register unit GEM3_(k+2)/2. With this arrangement, the number of the third light-emitting shift register units can be reduced by half. Of course, in practical applications, the second light emitting control signal lines EML2 corresponding to three, four or more adjacent rows of sub-pixels may be coupled to each other and then coupled to a third light-emitting shift register unit, which is not limited here.

It should be noted that, taking the k−1th row of sub-pixels and the k^{th} row of sub-pixels as an example, in the threshold compensation stage T2_k−1 corresponding to the k−1^{th} row of sub-pixels, the first light emitting control transistor M2 and the first reset control transistor M4 are both turned on, that is, the signals em1_k−1 and re1_k−1 are both valid signals (for example, high level) during this stage. Furthermore, in the signal writing phase T3_k−1, the signal ga_k−1 is a valid signal (e.g., a high level), and the data writing transistor M1 is turned on. In the threshold compensation stage T2_k corresponding to the k^{th} row of sub-pixels, the first light emitting control transistor M2 and the first reset control transistor M4 are both turned on, that is, the period in which the em1_k and re1_k signals are both valid signals (e.g., high level). Furthermore, in the signal writing phase T3_k, the signal ga_k is a valid signal (e.g., a high level), and the data writing transistor M1 is turned on. Therefore, if the falling edge of ga_k+m corresponding to the sub-pixels in the k+m^{th} row is before the rising edge of em2_k corresponding to the sub-pixels in the k^{th} row, but does not affect the normal operation of other timing sequences, the second light emitting control signal lines EML2 corresponding to the sub-pixels in the k^{th} row to the k+m^{th} row can be electrically connected to each other, m is an integer greater than or equal to 2.

Furthermore, the structures shown in FIGS. 11A and 11B can also support a plurality of display sub-areas. In an implementation, the plurality of third light-emitting shift register units belong to a plurality of third light-emitting register groups. The plurality of third light-emitting register groups correspond one-to-one to the plurality of display sub-areas. The plurality of third light-emitting register groups are coupled to the second light emitting control signal lines EML2 in the corresponding display sub-areas. Furthermore, the plurality of third light-emitting register groups correspond one-to-one to a plurality of third light-emitting trigger signal terminals. The input signal terminal of a first-level third light-emitting shift register unit in a third light-emitting register group is coupled to a corresponding third light-emitting trigger signal terminal. Alternatively, the plurality of third light-emitting register groups correspond to one third light-emitting trigger signal terminal. The input signal terminal of the first-level third light-emitting shift register unit in the first-level third light-emitting register group among the plurality of third light-emitting register groups is coupled to the third light-emitting trigger signal terminal. The driving output terminal of the last-level third light-emitting shift register unit of the preceding-level third light-emitting register group in two adjacent third light-emitting register groups is coupled to the input signal terminal of the first-level third light-emitting shift register unit of the following-level third light-emitting register group. Furthermore, the non-display area also includes a second light-emitting drive control circuit. The second light-emitting drive control circuit includes a plurality of second light-emitting shift register units. The first light emitting control signal line EML1 corresponding to each row of sub-pixels is coupled to a second light-emitting shift register unit in the plurality of second light-emitting shift register units. The plurality of second light-emitting shift register units belong to a plurality of second light-emitting register groups. The plurality of second light-emitting register groups correspond one-to-one to the plurality of display sub-areas. The plurality of second light-emitting register groups are coupled to the first light emitting control signal lines EML1 in the corresponding display sub-areas. The plurality of second light-emitting register groups correspond one-to-one to a plurality of second light-emitting trigger signal terminals. The input signal terminal of the first-level second light-emitting shift register unit in the second light-emitting register group is coupled to the corresponding second light-emitting trigger signal terminal. Alternatively, the plurality of second light-emitting register groups correspond to one second light-emitting trigger signal terminal. The input signal terminal of the first-level second light-emitting shift register unit in the first-level second light-emitting register group among the plurality of second light-emitting register groups is coupled to the second light-emitting trigger signal terminal. The driving output terminal of the last-level second light-emitting shift register unit of the preceding-level second light-emitting register group in two adjacent second light-emitting register groups is coupled to the input signal terminal of the first-level second light-emitting shift register unit of the following-level second light-emitting register group.

For example, as shown in FIGS. 11A and 11B, sub-areas Aa and Ab are displayed. The display sub-area Aa corresponds to the scan register group 230a, the second reset register group 222a, the fourth reset register group 224a, the third light-emitting register group 213a and the second light-emitting register group 212a. The display sub-area Ab corresponds to the scan register group 230b, the second reset register group 222b, the fourth reset register group 224b, the third light-emitting register group 213b and the second light-emitting register group 212b. The second light-emitting shift register unit GEM2_1 is coupled to the second light-emitting trigger signal terminal ESTV2. The third light-emitting shift register unit GEM3_1 is coupled to the third light-emitting trigger signal terminal ESTV3. Moreover, the timing diagram of signals corresponding to the structures shown in FIG. 11A and FIG. 11A is shown in FIG. 12. The working process thereof can refer to the description in the above embodiments, which will not be elaborated here.

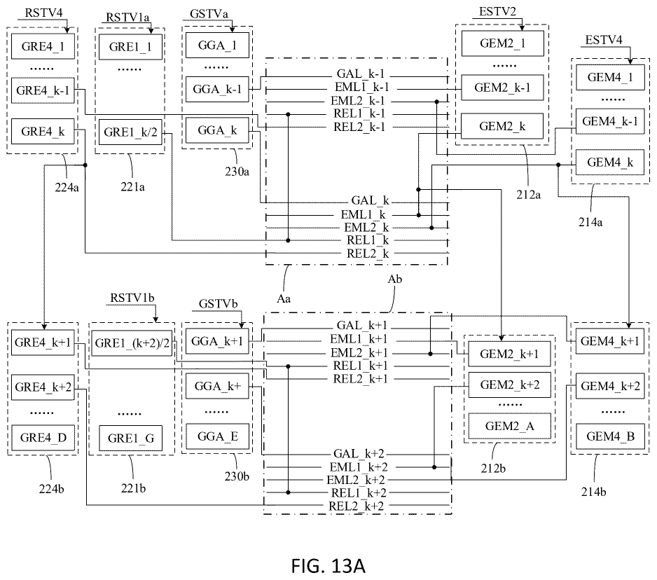

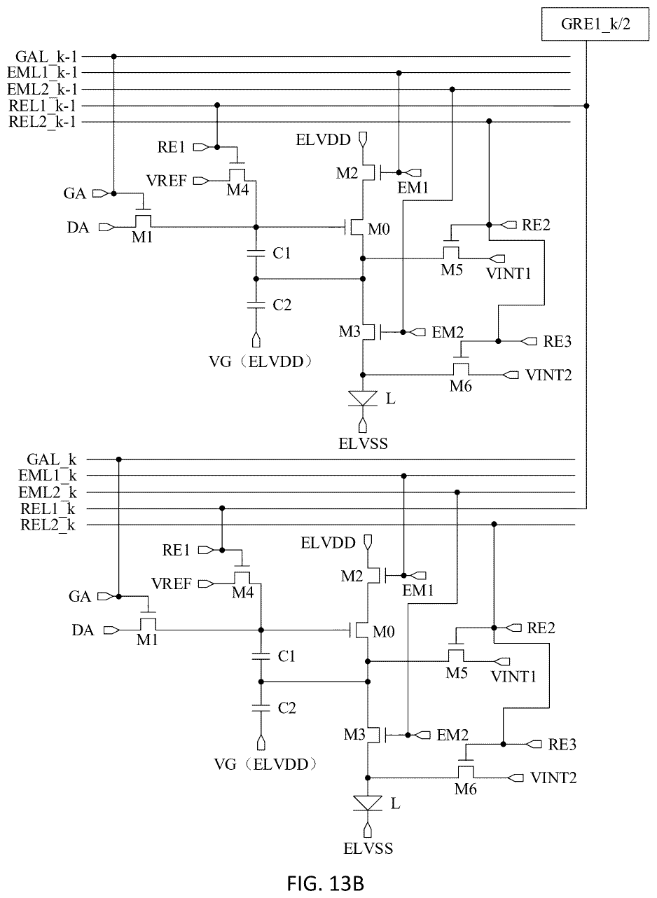

Embodiments of the present disclosure provide some further structural schematic diagrams of display panels. As shown in FIG. 13A, the implementation methods in the above embodiments are modified. Only the differences between these embodiments and the above-mentioned embodiment are described below, and the similarities are not repeated here.

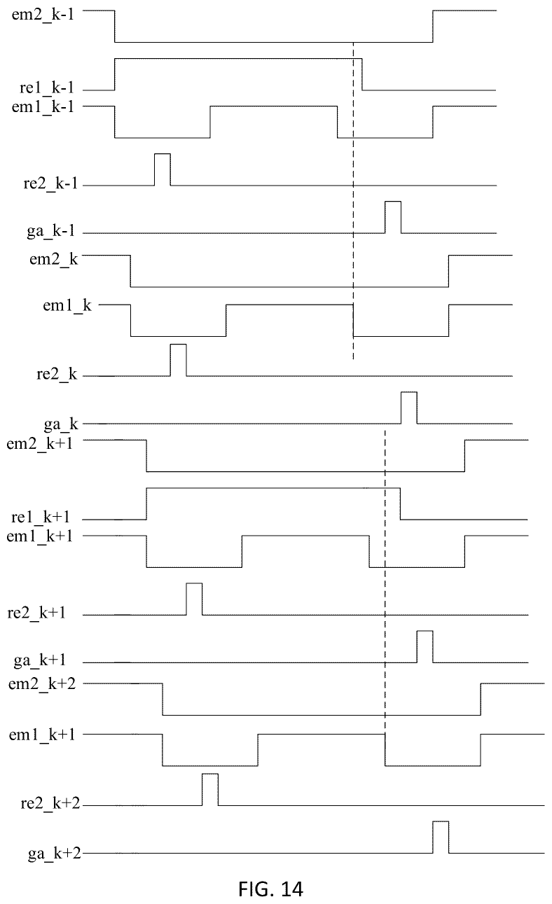

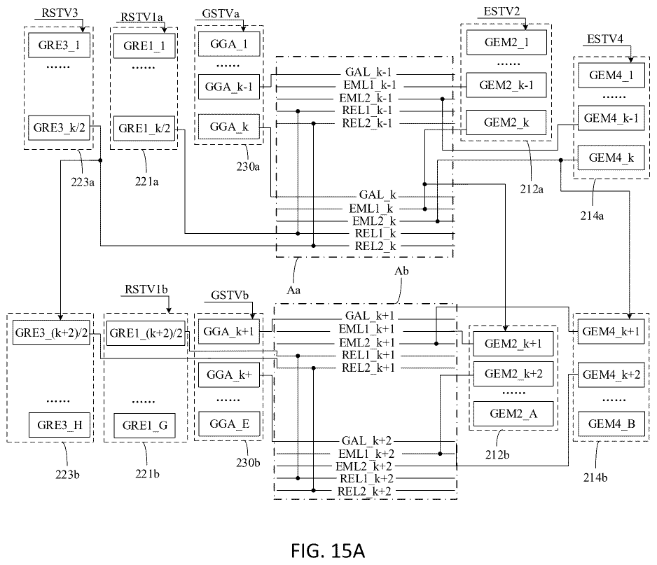

In embodiments of the present disclosure, as shown in FIGS. 13A and 13B, the pixel control circuit includes a first reset control circuit 140. The drive control circuit includes a first reset drive control circuit. The first reset drive control circuit includes a plurality of first reset shift register units GRE1_1^{~}GRE1_G (G is an integer greater than 0). Furthermore, the shift register units include the first reset shift register units. The control signal lines include first reset control signal lines REL1. The first reset control signal lines REL1 corresponding to two adjacent rows of sub-pixels are coupled to each other and then coupled to one of the plurality of first reset shift register units. For example, as shown in FIGS. 13A to 14, the first reset control signal line REL1_k−1 corresponding to the sub-pixels in the k−1^{th} row and the first reset control signal line REL1_k corresponding to the sub-pixels in the k^{th} row are coupled to each other and then coupled to the driving output terminal of the first reset shift register unit GRE1_k/2. The first reset control signal re1_k−1 is input to the first reset control signal line REL1_k−1 and the first reset control signal line REL1_k through the first reset shift register unit GRE1_k/2. Further, the first reset control signal line REL1_k+1 corresponding to the sub-pixels in the k+1^{th} row and the first reset control signal line REL1_k+2 corresponding to the sub-pixels in the k+2^{th} row are coupled to each other and then coupled to the driving output terminal of the first reset shift register unit GRE1_(k+2)/2. The first reset control signal re1_k+1 is input to the first reset control signal line REL1_k+1 and the first reset control signal line REL1_k+2 through the first reset shift register unit GRE1_(k+2)/2. With this arrangement, the number of first reset shift register units can be reduced by half. Of course, in practical applications, the first reset control signal lines REL1 corresponding to three, four or more adjacent rows of sub-pixels may be coupled to each other and then coupled to one first reset shift register unit, which is not limited here.

It should be noted that, taking the k−1^{th} row of sub-pixels and the k^{th} row of sub-pixels as an example, in the threshold compensation stage T2_k−1 corresponding to the k−1^{th} row of sub-pixels, the first light emitting control transistor M2 and the first reset control transistor M4 are both turned on, that is, the e signals m1_k−1 and re1_k−1 are both valid signals (for example, high level) during this stage. Furthermore, in the signal writing phase T3_k−1, the signal ga_k−1 is a valid signal (e.g., a high level), and the data writing transistor M1 is turned on. In the threshold compensation stage T2_k corresponding to the k^{th} row of sub-pixels, the first light emitting control transistor M2 and the first reset control transistor M4 are both turned on, that is, the period in which the signals em1_k and re1_k are both valid signals (e.g., high level). Furthermore, in the signal writing phase T3_k, the signal ga_k is a valid signal (e.g., a high level), and the data writing transistor M1 is turned on. Therefore, if the rising edge of ga_k+p corresponding to the sub-pixels in the k+p^{th} row is after the falling edge of re1_k corresponding to the sub-pixels in the k^{th} row, but does not affect the normal operation of other timing sequences, the first reset control signal lines REL1 corresponding to the sub-pixels in the k^{th} row to the k+p^{th} row can be electrically connected to each other, p is an integer greater than or equal to 2.

Moreover, taking the k^{th} row of sub-pixels as an example, in order to make the threshold compensation stages T2 corresponding to the rows of sub-pixels, corresponding to which the first reset control signal lines REL1 are electrically connected to each other, the same, the falling edge of re1_k−1 can also be adjusted. For example, the falling edge of re1_k−1 can be adjusted to be after the falling edge of em1_k.

Furthermore, the structures shown in FIGS. 13A and 13B can also support a plurality of display sub-areas. In an implementation, the plurality of first reset shift register units belong to a plurality of first reset register groups. The plurality of first reset register groups correspond one-to-one to the plurality of display sub-areas. The plurality of first reset register groups are coupled to the first reset control signal lines REL1 in the corresponding display sub-areas.

Furthermore, the plurality of first reset register groups correspond one-to-one to a plurality of first reset trigger signal terminals. The input signal terminal of the first-level first reset shift register unit in the first reset register group is coupled to the corresponding first reset trigger signal terminal. Alternatively, the plurality of first reset register groups correspond to one first reset trigger signal terminal. The input signal terminal of the first-level first reset shift register unit in the first-level first reset register group among the plurality of first reset register groups is coupled to the first reset register group. The driving output terminal of the last-level first reset shift register unit of the preceding-level first reset register group of two adjacent first reset register groups is coupled to the input signal terminal of the first-level first reset shift register unit of the following-level first reset register group.

For example, as shown in FIGS. 13A and 13B, sub-areas Aa and Ab are displayed. The display sub-area Aa corresponds to the scan register group 230a, the first reset register group 221a, the fourth reset register group 224a, the fourth light-emitting register group 214a and the second light-emitting register group 212a. The display sub-area Ab corresponds to the scan register group 230b, the first reset register group 221b, the fourth reset register group 224b, the fourth light-emitting register group 214b and the second light-emitting register group 212b. The first reset shift register unit GRE1_1 is coupled to the first reset trigger signal terminal RSTV1a. The first reset shift register unit GRE1_(k+2)/2 is coupled to the first reset trigger signal terminal RSTV1b. Moreover, the timing diagram of signals corresponding to the structures shown in FIG. 13A and FIG. 13B is shown in FIG. 14. The working process thereof can refer to the description in the above embodiments, which will not be elaborated here.

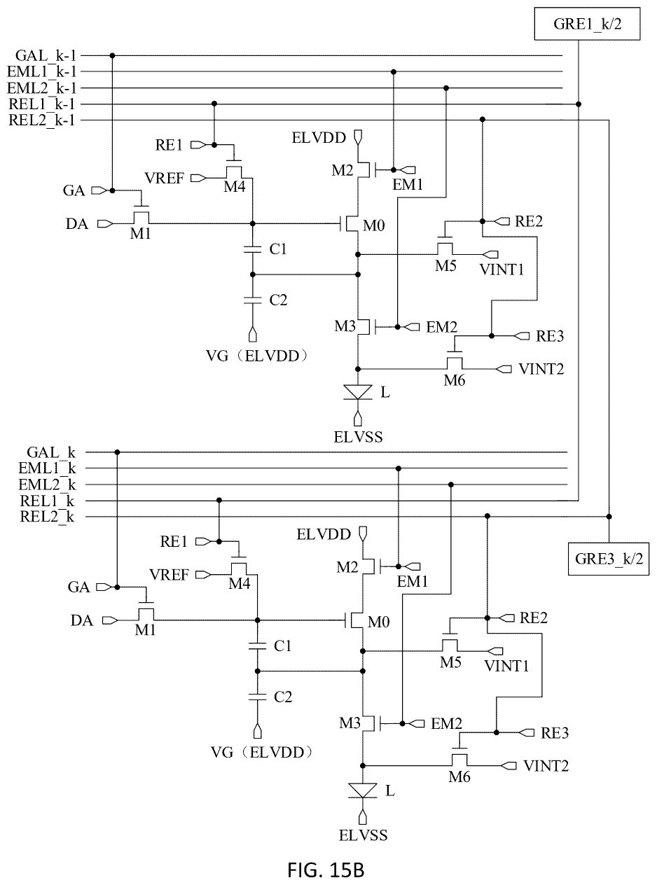

Embodiments of the present disclosure provide some further structural schematic diagrams of display panels. As shown in FIG. 15A, it is a modification of the implementation methods in the above embodiments. Only the differences between these embodiments and the above-mentioned embodiments are described below, and the similarities are not repeated here.

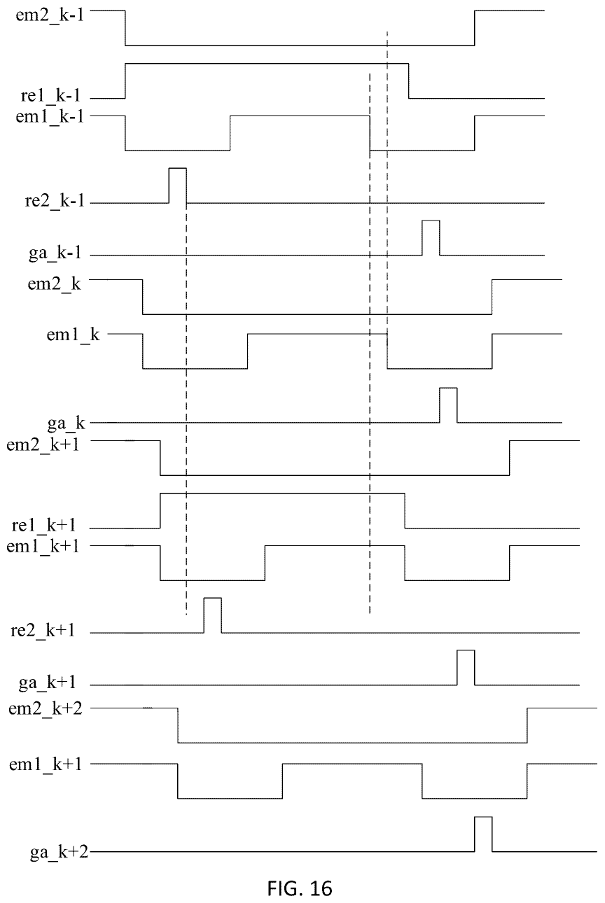

In embodiments of the present disclosure, as shown in FIGS. 15A and 15B, the pixel control circuit can also include a second reset control circuit 150. The drive control circuit includes a third reset drive control circuit. The third reset drive control circuit includes a plurality of third reset shift register units GRE3_1^{~}GRE3_H (H is an integer greater than 0). And, the shift register units include the third reset shift register units. The control signal lines include second reset control signal lines REL2. The second reset control signal lines REL2 corresponding to two adjacent rows of sub-pixels are coupled to each other and then coupled to one of the plurality of third reset shift register units. For example, as shown in FIGS. 15A to 16, the second reset control signal line REL2_k−1 corresponding to the sub-pixels in the k−1^{th} row and the second reset control signal line REL2_k corresponding to the sub-pixels in the k^{th} row are coupled to each other and then coupled to the driving output terminal of the third reset shift register unit GRE3_k/2. The second reset control signal re2_k−1 is input to the second reset control signal line REL2_k−1 and the second reset control signal line REL2_k through the third reset shift register unit GRE3_k/2. Further, the second reset control signal line REL2_k+1 corresponding to the sub-pixels in the k+1th row and the second reset control signal line REL2_k+2 corresponding to the sub-pixels in the k+2^{th} row are coupled to each other and then coupled to the driving output terminal of the third reset shift register unit GRE3_(k+2)/2. The second reset control signal re2_k+1 is input to the second reset control signal line REL2_k+1 and the second reset control signal line REL2_k+2 through the third reset shift register unit GRE3_(k+2)/2. With this arrangement, the number of the third reset shift register units can be reduced by half. Of course, in practical applications, the second reset control signal lines REL2 corresponding to three, four or more adjacent rows of sub-pixels may be coupled to each other and then coupled to one third reset shift register unit, which is not limited here.

It should be noted that, taking the k−1^{th} row of sub-pixels and the k^{th} row of sub-pixels as an example, in the threshold compensation stage T2_k−1 corresponding to the k−1^{th} row of sub-pixels, the first light emitting control transistor M2 and the first reset control transistor M4 are both turned on, that is, the signals em1_k−1 and re1_k−1 are both valid signals (for example, high level) during this stage. Furthermore, in the signal writing phase T3_k−1, the signal ga_k−1 is a valid signal (e.g., a high level), and the data writing transistor M1 is turned on. In the threshold compensation stage T2_k corresponding to the k^{th} row of sub-pixels, the first light emitting control transistor M2 and the first reset control transistor M4 are both turned on, that is, the period in which the signals em1_k and re1_k are both valid signals (e.g., high level). Furthermore, in the signal writing phase T3_k, the signal ga_k is a valid signal (e.g., a high level), and the data writing transistor M1 is turned on. Therefore, if the rising edge of ga_k+q corresponding to the sub-pixels in the k+q^{th} row is after the falling edge of re1_k corresponding to the sub-pixels in the k^{th} row, but does not affect the normal operation of other timing sequences, the first reset control signal lines REL1 corresponding to the sub-pixels in the k^{th} row to the k+q^{th} row can be electrically connected to each other, q is an integer greater than or equal to 2. In addition, if the rising edge of em1_k+w corresponding to the sub-pixels in the k+w^{th} row is before the falling edge of re2_k corresponding to the sub-pixels in the k^{th} row in the initialization stage T1, but does not affect the normal operation of other timing sequences, the second reset control signal lines REL2 corresponding to the sub-pixels in the k^{th} row to the k+w^{th} row can be electrically connected to each other, w is an integer greater than or equal to 2.

Moreover, taking the k^{th} row of sub-pixels as an example, in order to make the threshold compensation stages T2 corresponding to the rows of sub-pixels, corresponding to which the first reset control signal lines REL1 are electrically connected to each other, the same, the falling edge of re1_k−1 can also be adjusted, for example, the falling edge of re1_k−1 can be adjusted to after the falling edge of em1_k.

Furthermore, the structures shown in FIGS. 15A and 15B can also support a plurality of display sub-areas. In an implementation, the plurality of third reset shift register units belong to a plurality of third reset register groups. The plurality of third reset register groups correspond one-to-one to the plurality of display sub-areas. The plurality of third reset register groups are coupled to the second reset control signal lines REL2 in the corresponding display sub-areas. Furthermore, the plurality of third reset register groups correspond one-to-one to a plurality of third reset trigger signal terminals. The input signal terminal of the first-level third reset shift register unit in the third reset register group is coupled to the corresponding third reset trigger signal terminal. Alternatively, the plurality of third reset register groups correspond to one third reset trigger signal terminal. The input signal terminal of the first-level third reset shift register unit in the first-level third reset register group among the plurality of third reset register groups is coupled to the third reset trigger signal terminal. The driving output terminal of the last-level third reset shift register unit of the preceding-level third reset register group of two adjacent third reset register groups is coupled to the input signal terminal of the first-level third reset shift register unit of the following-level third reset register group.

For example, as shown in FIGS. 15A and 15B, sub-areas Aa and Ab are displayed. The display sub-area Aa corresponds to the scan register group 230a, the first reset register group 221a, the third reset register group 223a, the fourth light-emitting register group 214a and the second light-emitting register group 212a. The display sub-area Ab corresponds to the scan register group 230b, the first reset register group 221b, the third reset register group 223b, the fourth light-emitting register group 214b and the second light-emitting register group 212b. The third reset shift register unit GRE3_1 is coupled to the third reset trigger signal terminal RSTV3. Moreover, the timing diagram of signals corresponding to the structures shown in FIG. 15A and FIG. 15B is shown in FIG. 16. The working process thereof can refer to the description in the above embodiments, which will not be elaborated here.

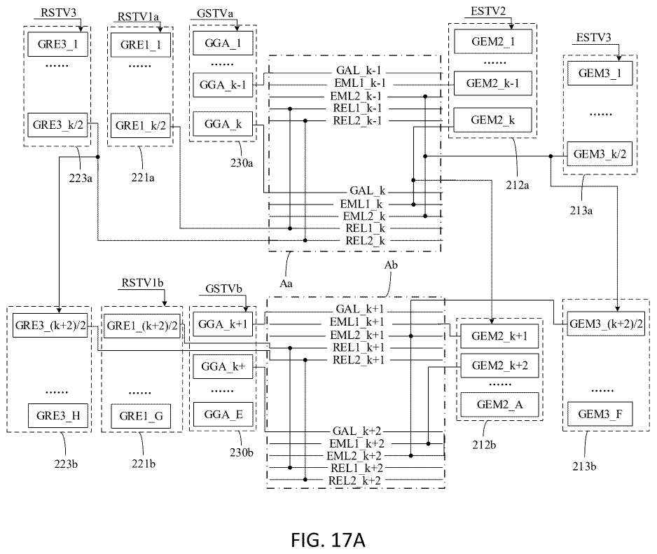

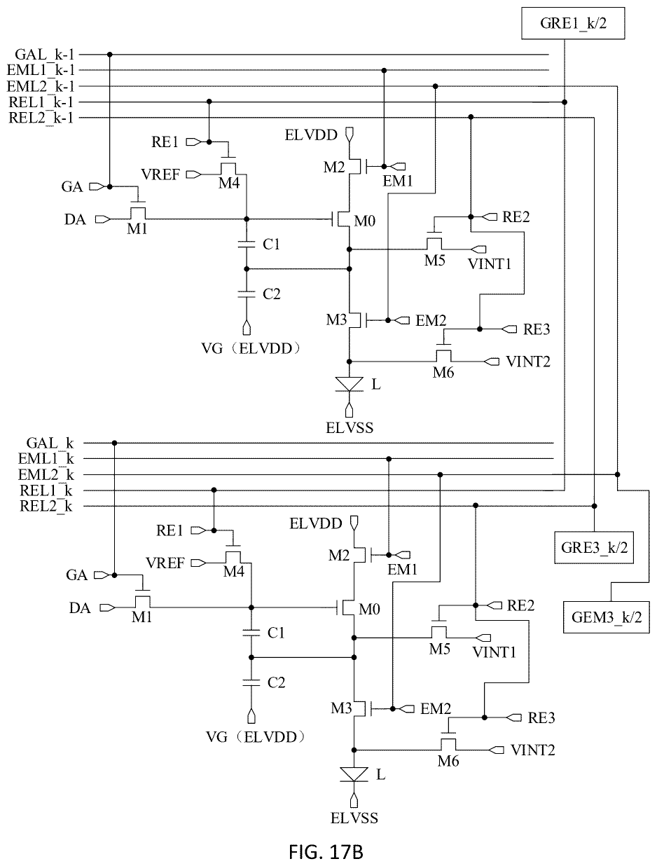

Embodiments of the present disclosure provide some further structural schematic diagrams of display panels. As shown in FIG. 17A, it illustrates a modification of the implementation methods in the above embodiments. Only the differences between these embodiments and the above-mentioned embodiments are described below, and the similarities are not repeated here.

In embodiments of the present disclosure, as shown in FIG. 17A and FIG. 17B, the pixel control circuit may also include a first reset control circuit 140, a second reset control circuit 150 and a second light emitting control circuit 130. For example, as shown in FIG. 17A and FIG. 17B, the first reset control signal line REL1_k−1 corresponding to the k−1^{th} row of sub-pixels and the first reset control signal line REL1_k corresponding to the k^{th} row of sub-pixels are coupled to each other and then coupled to the driving output terminal of the first reset shift register unit GRE1_k/2. Furthermore, the first reset control signal line REL1_k+1 corresponding to the sub-pixels in the k+1^{th} row and the first reset control signal line REL1_k+2 corresponding to the sub-pixels in the k+2^{th} row are coupled to each other and then coupled to the driving output terminal of the first reset shift register unit GRE1_(k+2)/2. The second reset control signal line REL2_k−1 corresponding to the sub-pixels in the k−1^{th} row and the second reset control signal line REL2_k corresponding to the sub-pixels in the k^{th} row are coupled to each other and then coupled to the driving output terminal of the third reset shift register unit GRE3_k/2. Furthermore, the second reset control signal line REL2_k+1 corresponding to the sub-pixels in the k+1^{th} row and the second reset control signal line REL2_k+2 corresponding to the sub-pixels in the k+2^{th} row are coupled to each other and then coupled to the driving output terminal of the third reset shift register unit GRE3_(k+2)/2. The second light emitting control signal line EML2_k−1 corresponding to the sub-pixels in the k−1^{th} row and the second light emitting control signal line EML2_k corresponding to the sub-pixels in the k^{th} row are coupled to each other and then coupled to the driving output terminal of the third light-emitting shift register unit GEM3_k/2. Furthermore, the second light emitting control signal line EML2_k+1 corresponding to the sub-pixels in the k+1^{th} row and the second light emitting control signal line EML2_k+2 corresponding to the sub-pixels in the k+2^{th} row are coupled to each other and then coupled to the driving output terminal of the third light-emitting shift register unit GEM3_(k+2)/2. For the rest of the content, please refer to the description in the above embodiments and will not be elaborated here.

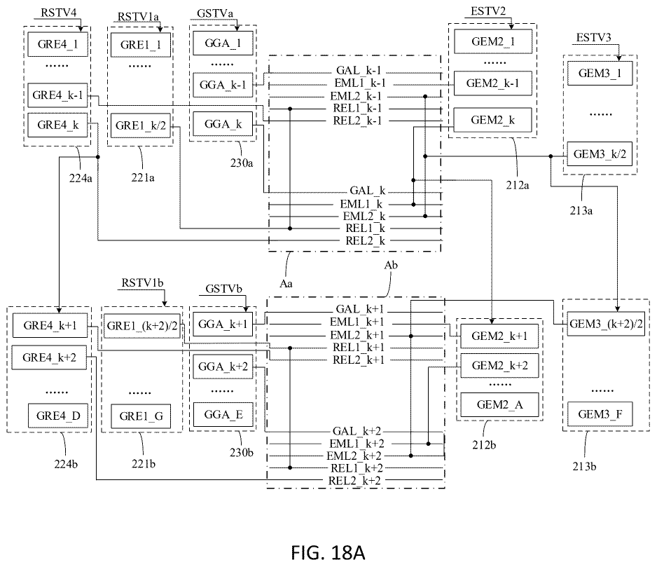

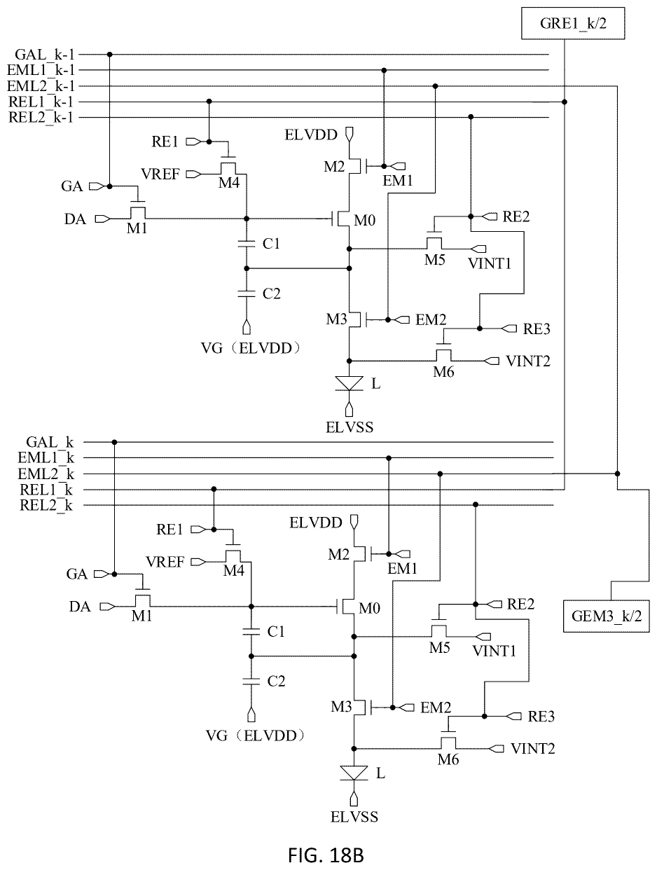

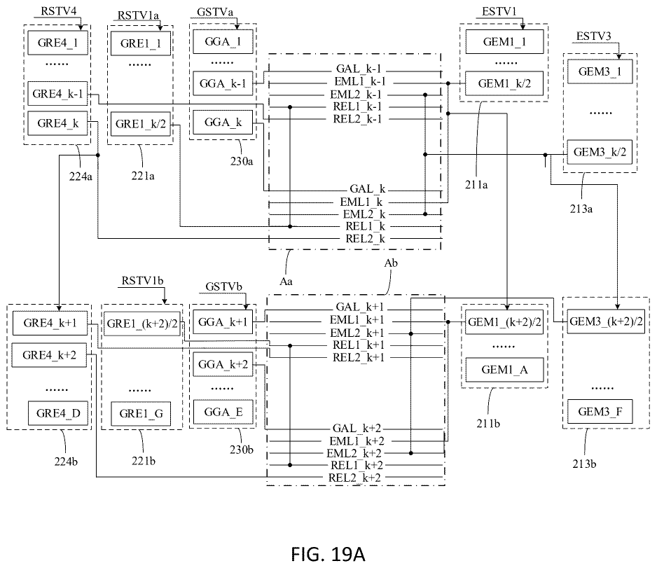

Embodiments of the present disclosure provide some further structural schematic diagrams of display panels. As shown in FIG. 18A, it illustrates a modification of the implementation methods in the above embodiments. Only the differences between these embodiments and the above-mentioned embodiments are described below, and the similarities are not repeated here.

In the embodiments of the present disclosure, as shown in FIG. 18A and FIG. 18B, the pixel control circuit may also include a first reset control circuit 140 and a second light emitting control circuit 130. The working process can refer to the description in the above embodiments and will not be described in detail here.

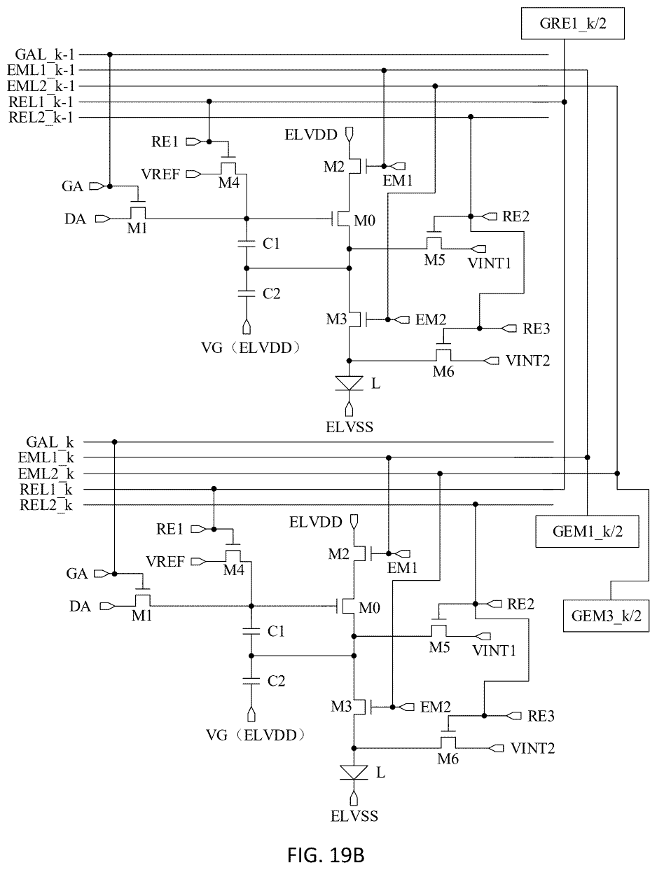

Embodiments of the present disclosure provide some further structural schematic diagrams of display panels. As shown in FIG. 19, it illustrates a modification of the implementation methods in the above embodiments. Only the differences between these embodiments and the above-mentioned embodiments are described below, and the similarities are not repeated here.

In embodiments of the present disclosure, as shown in FIG. 19A and FIG. 19B, the pixel control circuit may also include a first reset control circuit 140, a first light emitting control circuit 120 and a second light emitting control circuit 130. The working process can refer to the description in the above embodiments and will not be described in detail here.

Of course, the pixel control circuit may also include the first reset control circuit 140, the second reset control circuit 150, the first light emitting control circuit 120 and the second light emitting control circuit 130, which is not limited here.

Based on the same disclosed concept, embodiments of the present disclosure further provide a display device, including the above-mentioned display panel provided by embodiments of the present disclosure. The principle of solving the problem by the display device is similar to that of the aforementioned display panel, so the implementation of the display device can refer to the implementation of the aforementioned display panel, and the repeated parts will not be repeated here.

In an implementation, in embodiments of the present disclosure, the display device may be: a mobile phone, a tablet computer, a television, a monitor, a laptop computer, a digital photo frame, a navigator, or any other product or component with a display function. Other essential components of the display device should be understood by those skilled in the art and will not be described in detail herein and should not be construed as limiting the present disclosure.

Although preferred embodiments of the present disclosure have been described, additional changes and modifications may be made to these embodiments once those skilled in the art are aware of the basic inventive concepts. Therefore, it is intended that the appended claims be interpreted as including the preferred embodiments as well as all changes and modifications that fall within the scope of the present disclosure.

Obviously, those skilled in the art can make various changes and modifications to the embodiments of the present disclosure without departing from the spirit and scope of the embodiments of the present disclosure. Thus, if these modifications and variations of the embodiments of the present disclosure fall within the scope of the claims of the present disclosure and their equivalents, the present disclosure is also intended to include these modifications and variations.

1. A display panel comprising a display area and a non-display area;
wherein the display area comprises a plurality of sub-pixels and a plurality of control signal lines; wherein each of the plurality of sub-pixels comprises a pixel circuit, and the pixel circuit comprises: a light-emitting device, a driving transistor, a data writing circuit, and a pixel control circuit; wherein the driving transistor is coupled to the data writing circuit and the pixel control circuit respectively, the data writing circuit is configured to provide a data voltage at a data signal terminal to a gate of the driving transistor in response to a scan signal at a scan signal terminal, and the pixel control circuit is configured to control the driving transistor to generate a driving current for driving the light-emitting device to emit light;
pixel circuits in at least one row of sub-pixels among the plurality of sub-pixels are coupled to one control signal line among the plurality of control signal lines, and control signal lines corresponding to at least two adjacent rows of sub-pixels are coupled to each other;
the non-display area comprises a drive control circuit, and the drive control circuit comprises a plurality of shift register units; wherein the control signal lines coupled to each other are coupled to one shift register unit among the plurality of shift register units, and the shift register unit is configured to transmit a signal to pixel circuits through the control signal lines.

2. The display panel according to claim 1, wherein the pixel circuit comprises a first light emitting control circuit; wherein the first light emitting control circuit is coupled to a first electrode of the driving transistor, a first light emitting control signal terminal and a first power terminal; and the first light emitting control circuit is configured to provide a signal at the first power terminal to the first electrode of the driving transistor in response to a first light emitting control signal at the first light emitting control signal terminal;
the display area further comprises a plurality of first light emitting control signal lines; wherein first light emitting control signal terminals of pixel circuits in at least one row of sub-pixels among the plurality of sub-pixels are coupled to one first light emitting control signal line among the plurality of first light emitting control signal lines.

3. The display panel according to claim 2, wherein the pixel control circuit comprises the first light emitting control circuit, the drive control circuit comprises a first light-emitting drive control circuit, the first light-emitting drive control circuit comprises a plurality of first light-emitting shift register units, the shift register units comprise the first light-emitting shift register units, and the control signal lines comprise the first light emitting control signal lines;
first light emitting control signal lines corresponding to at least two adjacent rows of sub-pixels are coupled to each other and then coupled to one first light-emitting shift register unit among the plurality of first light-emitting shift register units.

4. The display panel according to claim 3, wherein the display area comprises a plurality of display sub-areas, the plurality of display sub-areas are arranged along a column direction of the sub-pixels, the plurality of first light-emitting shift register units comprise a plurality of first light-emitting register groups, the plurality of first light-emitting register groups correspond one-to-one to the plurality of display sub-areas, and the plurality of first light-emitting register groups are coupled to the first light emitting control signal lines in corresponding display sub-areas; wherein
the plurality of first light-emitting register groups correspond one-to-one to a plurality of first light-emitting trigger signal terminals, and an input signal terminal of a first-level first light-emitting shift register unit in the first light-emitting register group is coupled to a corresponding first light-emitting trigger signal terminal; or
the plurality of first light-emitting register groups correspond to one first light-emitting trigger signal terminal, an input signal terminal of a first-level first light-emitting shift register unit in a first-level first light-emitting register group among the plurality of first light-emitting register groups is coupled to the one first light-emitting trigger signal terminal, and a driving output terminal of a last-level first light-emitting shift register unit in a preceding-level first light-emitting register group of two adjacent first light-emitting register groups is coupled to the input signal terminal of the first-level first light-emitting shift register unit in a following-level first light-emitting register group.

5. The display panel according to claim 2, wherein the non-display area further comprises a second light-emitting drive control circuit, the second light-emitting drive control circuit comprises a plurality of second light-emitting shift register units;
the first light emitting control signal line corresponding to pixel circuits in each row of sub-pixels in the plurality of sub-pixels is coupled to one second light-emitting shift register unit among the plurality of second light-emitting shift register units.

6. The display panel according to claim 5, wherein the display area comprises a plurality of display sub-areas, the plurality of display sub-areas are arranged along a column direction of the sub-pixels, the plurality of second light-emitting shift register units comprise a plurality of second light-emitting register groups, the plurality of second light-emitting register groups correspond one-to-one to the plurality of display sub-areas, and the plurality of second light-emitting register groups are coupled to the first light emitting control signal lines in corresponding display sub-areas; wherein
the plurality of second light-emitting register groups correspond one-to-one to a plurality of second light-emitting trigger signal terminals, and an input signal terminal of a first-level second light-emitting shift register unit in the second light-emitting register group is coupled to a corresponding second light-emitting trigger signal terminal; or
the plurality of second light-emitting register groups correspond to one second light-emitting trigger signal terminal, an input signal terminal of a first-level second light-emitting shift register unit in a first-level second light-emitting register group among the plurality of second light-emitting register groups is coupled to the one second light-emitting trigger signal terminal, and a driving output terminal of a last-level second light-emitting shift register unit in a preceding-level second light-emitting register group of two adjacent second light-emitting register groups is coupled to the input signal terminal of the first-level second light-emitting shift register unit in a following-level second light-emitting register group.

7. The display panel according to claim 1, wherein the pixel circuit comprises a second light emitting control circuit; the second light emitting control circuit is coupled to a second electrode of the driving transistor, the light-emitting device and a second light emitting control signal terminal; the second light emitting control circuit is configured to enable conduction between the second electrode of the driving transistor and the light-emitting device in response to a second light emitting control signal at the second light emitting control signal terminal;
the display area further comprises a plurality of second light emitting control signal lines; wherein second light emitting control signal terminals of pixel circuits in at least one row of sub-pixels among the plurality of sub-pixels are coupled to one second light emitting control signal line among the plurality of second light emitting control signal lines.

8. The display panel according to claim 7, wherein the pixel control circuit comprises the second light emitting control circuit, the drive control circuit comprises a third light-emitting drive control circuit, the third light-emitting drive control circuit comprises a plurality of third light-emitting shift register units, and the shift register units comprise the third light-emitting shift register units;
the control signal lines comprise the second light emitting control signal lines, and second light emitting control signal lines corresponding to at least two adjacent rows of sub-pixels are coupled to each other and then coupled to one third light-emitting shift register unit among the plurality of third light-emitting shift register units.

9. The display panel according to claim 8, wherein the display area comprises a plurality of display sub-areas, the plurality of display sub-areas are arranged along a column direction of the sub-pixels, the plurality of third light-emitting shift register units comprise a plurality of third light-emitting register groups, the plurality of third light-emitting register groups correspond one-to-one to the plurality of display sub-areas, and the plurality of third light-emitting register groups are coupled to the second light emitting control signal lines in corresponding display sub-areas; wherein
the plurality of third light-emitting register groups correspond one-to-one to a plurality of third light-emitting trigger signal terminals, and an input signal terminal of a first-level third light-emitting shift register unit in the third light-emitting register group is coupled to a corresponding third light-emitting trigger signal terminal; or
the plurality of third light-emitting register groups correspond to one third light-emitting trigger signal terminal, an input signal terminal of a first-level third light-emitting shift register unit in a first-level third light-emitting register group among the plurality of third light-emitting register groups is coupled to the one third light-emitting trigger signal terminal, and a driving output terminal of a last-level third light-emitting shift register unit in a preceding-level third light-emitting register group of two adjacent third light-emitting register groups is coupled to the input signal terminal of the first-level third light-emitting shift register unit in a following-level third light-emitting register group.

10. The display panel according to claim 7, wherein the non-display area further comprises a fourth light-emitting drive control circuit, the fourth light-emitting drive control circuit comprises a plurality of fourth light-emitting shift register units;
the second light emitting control signal line corresponding to pixel circuits in each row of sub-pixels in the plurality of sub-pixels is coupled to one fourth light-emitting shift register unit among the plurality of fourth light-emitting shift register units.

11. The display panel according to claim 10, wherein the display area comprises a plurality of display sub-areas, the plurality of display sub-areas are arranged along a column direction of the sub-pixels, the plurality of fourth light-emitting shift register units comprise a plurality of fourth light-emitting register groups, the plurality of fourth light-emitting register groups correspond one-to-one to the plurality of display sub-areas, and the plurality of fourth light-emitting register groups are coupled to the second light emitting control signal lines in corresponding display sub-areas; wherein
the plurality of fourth light-emitting register groups correspond one-to-one to a plurality of fourth light-emitting trigger signal terminals, and an input signal terminal of a first-level fourth light-emitting shift register unit in the fourth light-emitting register group is coupled to a corresponding fourth light-emitting trigger signal terminal; or
the plurality of fourth light-emitting register groups correspond to one fourth light-emitting trigger signal terminal, an input signal terminal of a first-level fourth light-emitting shift register unit in a first-level fourth light-emitting register group among the plurality of fourth light-emitting register groups is coupled to the one fourth light-emitting trigger signal terminal, and a driving output terminal of a last-level fourth light-emitting shift register unit in a preceding-level fourth light-emitting register group of two adjacent fourth light-emitting register groups is coupled to the input signal terminal of the first-level fourth light-emitting shift register unit in a following-level fourth light-emitting register group.

12. The display panel according to claim 1, wherein the pixel circuit comprises a first reset control circuit; the first reset control circuit is coupled to the gate of the driving transistor, a first reset control signal terminal and a reference signal terminal; the first reset control circuit is configured to provide a signal at the reference signal terminal to the gate of the driving transistor in response to a first reset control signal at the first reset control signal terminal;
the display area further comprises a plurality of first reset control signal lines; wherein first reset control signal terminals of pixel circuits in at least one row of sub-pixels among the plurality of sub-pixels are coupled to one first reset control signal line among the plurality of first reset control signal lines.

13. The display panel according to claim 12, wherein the pixel control circuit comprises the first reset control circuit, the drive control circuit comprises a first reset drive control circuit, the first reset drive control circuit comprises a plurality of first reset shift register units, and the shift register units comprise the first reset shift register units;
the control signal lines comprise the first reset control signal lines, and first reset control signal lines corresponding to at least two adjacent rows of sub-pixels are coupled to each other and then coupled to one first reset shift register unit among the plurality of first reset shift register units.

14. The display panel according to claim 13, wherein the display area comprises a plurality of display sub-areas, the plurality of display sub-areas are arranged along a column direction of the sub-pixels, the plurality of first reset shift register units comprise a plurality of first reset register groups, the plurality of first reset register groups correspond one-to-one to the plurality of display sub-areas, and the plurality of first reset register groups are coupled to the first reset control signal lines in corresponding display sub-areas; wherein
the plurality of first reset register groups correspond one-to-one to a plurality of first reset trigger signal terminals, and an input signal terminal of a first-level first reset shift register unit in the first reset register group is coupled to a corresponding first reset trigger signal terminal; or
the plurality of first reset register groups correspond to one first reset trigger signal terminal, an input signal terminal of a first-level first reset shift register unit in a first-level first reset register group among the plurality of first reset register groups is coupled to the one first reset trigger signal terminal, and a driving output terminal of a last-level first reset shift register unit in a preceding-level first reset register group of two adjacent first reset register groups is coupled to the input signal terminal of the first-level first reset shift register unit in a following-level first reset register group.

15. The display panel according to claim 12, wherein the non-display area further comprises a second reset drive control circuit, the second reset drive control circuit comprises a plurality of second reset shift register units;
the first reset control signal line corresponding to pixel circuits in each row of sub-pixels in the plurality of sub-pixels is coupled to one second reset shift register unit among the plurality of second reset shift register units.

16. The display panel according to claim 15, wherein the display area comprises a plurality of display sub-areas, the plurality of display sub-areas are arranged along a column direction of the sub-pixels, the plurality of second reset shift register units comprise a plurality of second reset register groups, the plurality of second reset register groups correspond one-to-one to the plurality of display sub-areas, and the plurality of second reset register groups are coupled to the first reset control signal lines in corresponding display sub-areas; wherein
the plurality of second reset register groups correspond one-to-one to a plurality of second reset trigger signal terminals, and an input signal terminal of a first-level second reset shift register unit in the second reset register group is coupled to a corresponding second reset trigger signal terminal; or
the plurality of second reset register groups correspond to one second reset trigger signal terminal, an input signal terminal of a first-level second reset shift register unit in a first-level second reset register group among the plurality of second reset register groups is coupled to the one second reset trigger signal terminal, and a driving output terminal of a last-level second reset shift register unit in a preceding-level second reset register group in two adjacent second reset register groups is coupled to the input signal terminal of the first-level second reset shift register unit in a following-level second reset register group.

17. The display panel according to claim 1, wherein the pixel circuit comprises a second reset control circuit; the second reset control circuit is coupled to a second electrode of the driving transistor, a second reset control signal terminal and a first initialization signal terminal; the second reset control circuit is configured to provide a signal at the first initialization signal terminal to the second electrode of the driving transistor in response to a second reset control signal at the second reset control signal terminal;
the display area further comprises a plurality of second reset control signal lines; wherein second reset control signal terminals of pixel circuits in at least one row of sub-pixels among the plurality of sub-pixels are coupled to one second reset control signal line among the plurality of second reset control signal lines.

18. The display panel according to claim 17, wherein the pixel control circuit comprises the second reset control circuit, the drive control circuit comprises a third reset drive control circuit, the third reset drive control circuit comprises a plurality of third reset shift register units, and the shift register units comprise the third reset shift register units;
the control signal lines comprise the second reset control signal lines, and second reset control signal lines corresponding to at least two adjacent rows of sub-pixels are coupled to each other and then coupled to one third reset shift register unit among the plurality of third reset shift register units.

19. The display panel according to claim 18, wherein the display area comprises a plurality of display sub-areas, the plurality of display sub-areas are arranged along a column direction of the sub-pixels, the plurality of third reset shift register units comprise a plurality of third reset register groups, the plurality of third reset register groups correspond one-to-one to the plurality of display sub-areas, and the plurality of third reset register groups are coupled to the second reset control signal lines in corresponding display sub-areas; wherein
the plurality of third reset register groups correspond one-to-one to a plurality of third reset trigger signal terminals, and an input signal terminal of a first-level third reset shift register unit in the third reset register group is coupled to a corresponding third reset trigger signal terminal; or
the plurality of third reset register groups correspond to one third reset trigger signal terminal, an input signal terminal of a first-level third reset shift register unit in a first-level third reset register group among the plurality of third reset register groups is coupled to the one third reset trigger signal terminal and a driving output terminal of a last-level third reset shift register unit in a previous third reset register group of two adjacent third reset register groups is coupled to the input signal terminal of the first-level third reset shift register unit in a following-level third reset register group.

20. The display panel according to claim 17, wherein the non-display area further comprises a fourth reset drive control circuit, the fourth reset drive control circuit comprise a plurality of fourth reset shift register units;
the second reset control signal line corresponding to pixel circuits in each row of sub-pixels in the plurality of sub-pixels is coupled to one fourth reset shift register unit among the plurality of fourth reset shift register units;
wherein the display area comprises a plurality of display sub-areas, the plurality of display sub-areas are arranged along a column direction of the sub-pixels, the plurality of fourth reset shift register units comprises a plurality of fourth reset register groups, the plurality of fourth reset register groups correspond one-to-one to the plurality of display sub-areas, and the plurality of fourth reset register groups are coupled to the second reset control signal lines in corresponding display sub-areas; wherein
the plurality of fourth reset register groups correspond one-to-one to a plurality of fourth reset trigger signal terminals, and an input signal terminal of a first-level fourth reset shift register unit in the fourth reset register group is coupled to a corresponding fourth reset trigger signal terminal; or
the plurality of fourth reset register groups correspond to one fourth reset trigger signal terminal, an input signal terminal of a first-level fourth reset shift register unit in a first-level fourth reset register group among the plurality of fourth reset register groups is coupled to the one fourth reset trigger signal terminal, and a driving output terminal of a last-level fourth reset shift register unit in a preceding-level fourth reset register group of two adjacent fourth reset register groups is coupled to the input signal terminal of the first-level fourth reset shift register unit in a following-level fourth reset register group.

21-26. (canceled)
